(19) United States
(12) Patent Application Publication
(10) Pub. No.: US 2025/0056140 A1
(43) Pub. Date: Feb. 13, 2025

(54) SOLID-STATE IMAGING DEVICE AND ELECTRONIC EQUIPMENT

(71) Applicant: SONY SEMICONDUCTOR SOLUTIONS CORPORATION, KANAGAWA (JP)

(72) Inventors: SHUHEI MAEDA, KANAGAWA (JP); TAKEYOSHI KOMOTO, KANAGAWA (JP)

(21) Appl. No.: 18/717,685

(22) PCT Filed: Dec. 6, 2022
(86) PCT No.: PCT/JP2022/044873

§ 371 Date: Jun. 7, 2024

(30) Foreign Application Priority Data
Dec. 15, 2021 (JP) 2021-203484

(51) Int. Cl. H04N 25/78; H04N 25/77; H04N 25/778

(52) U.S. Cl. CPC H04N 25/78; H04N 25/77; H04N 25/778

(57) ABSTRACT

A solid-state imaging device according to an embodiment includes a first photoelectric conversion section that generates an electric charge corresponding to an incident light amount, a second photoelectric conversion section that is adjacent to the first photoelectric conversion section and generates an electric charge corresponding to an incident light amount, a floating diffusion region that accumulates the electric charge generated in at least one of the first photoelectric conversion section and the second photoelectric conversion section, a first transfer transistor connected between the first photoelectric conversion section and the floating diffusion region, a second transfer transistor connected between the second photoelectric conversion section and the floating diffusion region, a first drive line connected to a gate of the first transfer transistor, and a second drive line connected to a gate of the second transfer transistor. Coupling capacitance between the second drive line and the floating diffusion region is smaller than coupling capacitance between the first drive line and the floating diffusion region.

### FIELD

The present disclosure relates to a solid-state imaging device and electronic equipment.

### BACKGROUND

In recent years, so-called image plane phase difference autofocus for detecting a phase difference using an image plane phase difference pixel configured by a pair of adjacent pixels has been attracting attention as a technology for implementing an autofocus function of an imaging device. In a solid-state imaging device adopting the image plane phase difference autofocus, for example, it is possible to focus on a subject on the basis of a signal intensity ratio of an output signal output from each of the pair of pixels configuring the image plane phase difference pixel.

### CITATION LIST

### Patent Literature

Patent Literature 1: JP 2021-5675 A
Patent Literature 2: JP 2018/105334 B

### SUMMARY

### Technical Problem

However, with further miniaturization in recent years, it has been becoming difficult to reduce variations in output signals between the pair of pixels configuring the image plane phase difference pixel. Therefore, in the related art, there is a problem in that image quality is deteriorated because of white point deterioration or the like at the time of inter-pixel reading.

Therefore, the present disclosure proposes a solid-state imaging device and electronic equipment capable of suppressing deterioration in image quality.

### Solution to Problem

To solve the above-described problem, a solid-state imaging device according to one aspect of the present disclosure includes: a first photoelectric conversion section that generates an electric charge corresponding to an incident light amount; a second photoelectric conversion section that is adjacent to the first photoelectric conversion section and generates an electric charge corresponding to an incident light amount; a floating diffusion region that accumulates the electric charge generated in at least one of the first photoelectric conversion section and the second photoelectric conversion section; a first transfer transistor connected between the first photoelectric conversion section and the floating diffusion region; a second transfer transistor connected between the second photoelectric conversion section and the floating diffusion region; a first drive line connected to a gate of the first transfer transistor; and a second drive line connected to a gate of the second transfer transistor. In the solid-state imaging device, coupling capacitance between the second drive line and the floating diffusion region is smaller than coupling capacitance between the first drive line and the floating diffusion region.

A solid-state imaging device according to another aspect of the present disclosure includes: a first photoelectric conversion section that generates an electric charge corresponding to an incident light amount; a second photoelectric conversion section that is adjacent to the first photoelectric conversion section and generates an electric charge corresponding to an incident light amount; a floating diffusion region that accumulates the electric charge generated in at least one of the first photoelectric conversion section and the second photoelectric conversion section; a first transfer transistor connected between the first photoelectric conversion section and the floating diffusion region; a second transfer transistor connected between the second photoelectric conversion section and the floating diffusion region; a first drive line connected to a gate of the first transfer transistor; a second drive line connected to a gate of the second transfer transistor; and a drive circuit that applies a drive signal to each of the first drive line and the second drive line. In the solid-state imaging device, the first photoelectric conversion section, the first transfer transistor, and the floating diffusion region configure a first pixel, the second photoelectric conversion section, the second transfer transistor, and the floating diffusion region configure a second pixel, and the drive circuit applies a first drive signal to the first drive line at a time of read from the first pixel and applies a third drive signal to the second drive line after applying a second drive signal to the first drive line at a time of read from the second pixel.

A solid-state imaging device according to still another aspect of the present disclosure includes: a first photoelectric conversion section that generates an electric charge corresponding to an incident light amount; a second photoelectric conversion section that is adjacent to the first photoelectric conversion section and generates an electric charge corresponding to an incident light amount; a floating diffusion region that accumulates the electric charge generated in at least one of the first photoelectric conversion section and the second photoelectric conversion section; a first transfer transistor connected between the first photoelectric conversion section and the floating diffusion region; a second transfer transistor connected between the second photoelectric conversion section and the floating diffusion region; a first drive line connected to a gate of the first transfer transistor; a second drive line connected to a gate of the second transfer transistor; and a drive circuit that applies a drive signal to each of the first drive line and the second drive line. In the solid-state imaging device, the first photoelectric conversion section, the first transfer transistor, and the floating diffusion region configure a first pixel, the second photoelectric conversion section, the second transfer transistor, and the floating diffusion region configure a second pixel, the drive circuit applies a first drive signal to the first drive line at a time of read from the first pixel and applies a second drive signal to the first drive line and applies a third drive signal to the second drive line at a time of read from the second pixel, and a voltage level of at least one of the second drive signal and the third drive signal is lower than a voltage level of the first drive signal.

### BRIEF DESCRIPTION OF DRAWINGS

FIG. 1 is a block diagram illustrating a schematic configuration example of electronic equipment mounted with a solid-state imaging device according to a first embodiment of the present disclosure.

FIG. 2 is a block diagram illustrating a schematic configuration example of a CMOS solid-state imaging device according to the first embodiment of the present disclosure.

FIG. 3 is a circuit diagram illustrating a schematic configuration example of a pixel according to the first embodiment of the present disclosure.

FIG. 4 is a circuit diagram illustrating a schematic configuration example of a pixel including an FD shared structure according to the first embodiment of the present disclosure.

FIG. 5 is a diagram illustrating a laminated structure example of an image sensor according to the first embodiment of the present disclosure.

FIG. 6 is a sectional view illustrating a basic sectional structure example of the pixel according to the first embodiment of the present disclosure.

FIG. 7 is a schematic plan view illustrating a planar layout example of an image plane phase difference pixel according to the first embodiment of the present disclosure.

FIG. 8 is a timing chart illustrating a basic operation example of the image plane phase difference pixel according to the first embodiment of the present disclosure.

FIG. 9 is a diagram for explaining an example of an adjustment method for a transfer boost amount according to the first embodiment of the present disclosure.

FIG. 10 is a vertical sectional view illustrating a sectional structure example of the image plane phase difference pixel taken along line A-A in FIG. 9.

FIG. 11 is a process sectional view for explaining an example of a manufacturing method according to the first embodiment of the present disclosure (part 1).

FIG. 12 is a process sectional view for explaining the example of the manufacturing method according to the first embodiment of the present disclosure (part 2).

FIG. 13 is a process sectional view for explaining the example of the manufacturing method according to the first embodiment of the present disclosure (part 3).

FIG. 14 is a process sectional view for explaining the example of the manufacturing method according to the first embodiment of the present disclosure (part 4).

FIG. 15 is a process sectional view for explaining the example of the manufacturing method according to the first embodiment of the present disclosure (part 5).

FIG. 16 is a vertical sectional view illustrating a sectional structure example of an image plane phase difference pixel according to a modification of a third method of the first embodiment of the present disclosure.

FIG. 17 is a diagram for explaining effects in a case in which a first method according to the first embodiment of the present disclosure is applied to parts of right pixels and left pixels.

FIG. 18 is a schematic plan view illustrating a planar layout example of an image plane phase difference pixel according to a second embodiment of the present disclosure.

FIG. 19 is a circuit diagram illustrating a schematic configuration example of a pixel according to the second embodiment of the present disclosure.

FIG. 20 is a timing chart illustrating an operation example of an image plane phase difference image according to a third embodiment of the present disclosure.

FIG. 21 is a timing chart illustrating an operation example of an image plane phase difference image according to the third embodiment of the present disclosure.

FIG. 22 is a timing chart illustrating an operation example of an image plane phase difference image according to a modification of the third embodiment of the present disclosure.

FIG. 23 is a block diagram illustrating an example of a schematic functional configuration of a smartphone.

FIG. 24 is a block diagram depicting an example of schematic configuration of a vehicle control system.

FIG. 25 is a diagram of assistance in explaining an example of installation positions of an outside-vehicle information detecting section and an imaging section.

FIG. 26 is a view depicting an example of a schematic configuration of an endoscopic surgery system.

FIG. 27 is a block diagram depicting an example of a functional configuration of a camera head and a camera control unit (CCU).

### DESCRIPTION OF EMBODIMENTS

Embodiments of the present disclosure are explained in detail below with reference to the drawings. Note that, in the embodiments explained below, redundant explanation is omitted by denoting the same parts with the same reference numerals and signs.

The present disclosure is explained according to the item order explained below.
1. First Embodiment
1.1 Configuration example of electronic equipment (an imaging device)
1.2 Configuration Example of a solid-state imaging device
1.3 Configuration example of a pixel
1.3.1 Configuration example of a pixel including an FD shared structure
1.4 Basic functional example of a unit pixel
1.5 Laminated structure example of the solid-state imaging device
1.6 Basic structure example of the pixel
1.7 Planar layout example of an image plane phase difference pixel
1.8 Basic operation example of the image plane phase difference pixel
1.9 Problems in the image plane phase difference pixel
1.10 Example of an adjustment method for a transfer boost amount
1.10.1 First method
1.10.2 Second method
1.10.3 Third method
1.10.3.1 Example of a manufacturing method
1.10.3.2 Modification of a third method
1.11 Summary
2. Second Embodiment
2.1 Planar layout example of an image plane phase difference pixel
2.2 Configuration example of a pixel
2.3 Summary
3. Third Embodiment
3.1 Operation example of an image plane phase difference pixel
3.2 Summary
4. Fourth Embodiment
4.1 Operation example of an image plane phase difference pixel
4.1.1 Modification of an operation of the image plane phase difference pixel
4.2 Summary
5. Application example to a smartphone
6. Application example to a mobile body
7. Application example to an endoscopic surgery system

### 1. First Embodiment

First, a first embodiment of the present disclosure is explained in detail with reference to the drawings. Note that, in the present embodiment, a case in which a technology according to the present embodiment is applied to a CMOS (Complementary Metal-Oxide-Semiconductor) type solid-state imaging device (hereinafter also referred to as image sensor) is illustrated. However, not only this, but, for example, the technology according to the present embodiment can be applied to various sensors including a photoelectric conversion element such as a CCD (Charge Coupled Device) type solid-state imaging device, a ToF (Time of Flight) sensor, or an EVS (Event-based Vision Sensor).

### 1.1 Configuration Example of Electronic Equipment (an Imaging Device)

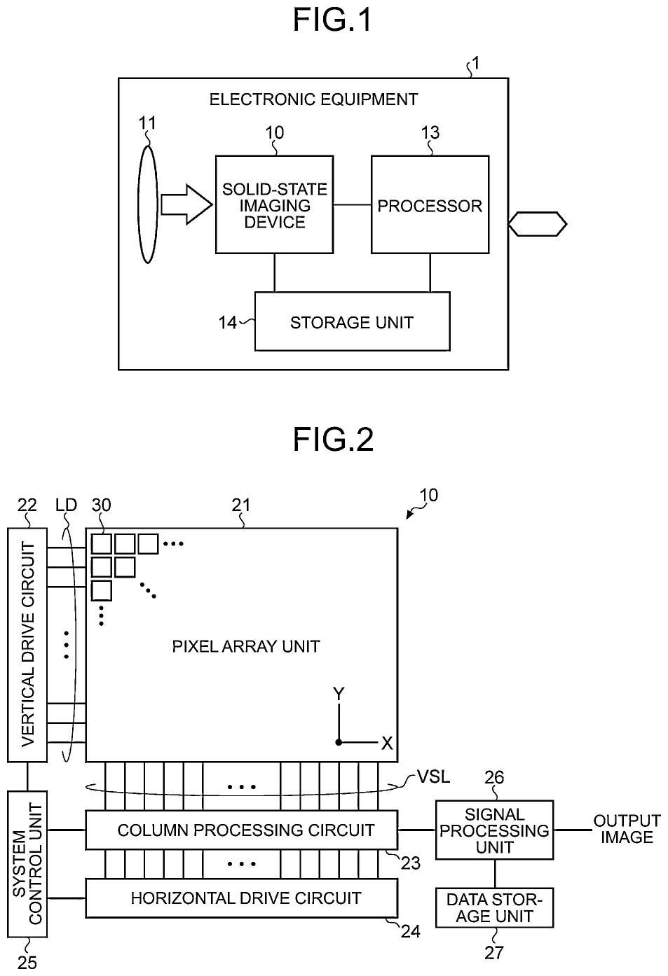

FIG. 1 is a block diagram illustrating a schematic configuration example of electronic equipment (an imaging device) mounted with a solid-state imaging device according to the first embodiment. As illustrated in FIG. 1, an imaging device 1 includes, for example, an imaging lens 11, a solid-state imaging device 10, a storage unit 14, and a processor 13.

The imaging lens 11 is an example of an optical system that condenses incident light and forms an image of the incident light on a light receiving surface of the solid-state imaging device 10. The light receiving surface may be a surface on which photoelectric conversion elements are arrayed in the solid-state imaging device 10. The solid-state imaging device 10 photoelectrically converts the incident light to generate image data. The solid-state imaging device 10 executes predetermined signal processing such as noise removal and white balance adjustment on the generated image data.

The storage unit 14 is configured by, for example, a flash memory, a DRAM (Dynamic Random Access Memory), an SRAM (Static Random Access Memory), or the like and records image data or the like input from the solid-state imaging device 10.

The processor 13 is configured using, for example, a CPU (Central Processing Unit) or the like and can include an application processor that executes an operating system, various kinds of application software, and the like, a GPU (Graphics Processing Unit), a baseband processor, and the like. The processor 13 executes various kinds of processing corresponding to necessity on image data input from the solid-state imaging device 10, image data read from the storage unit 14, and the like, executes display to a user, and transmits the image data and the like to the outside via a predetermined network.

### 1.2 Configuration Example of a Solid-State Imaging Device

FIG. 2 is a block diagram illustrating a schematic configuration example of a CMOS solid-state imaging device according to the first embodiment. Here, the CMOS solid-state imaging device is an image sensor created by applying or partially using a CMOS process. For example, the solid-state imaging device 10 according to the present embodiment is configured by a back-illuminated image sensor.

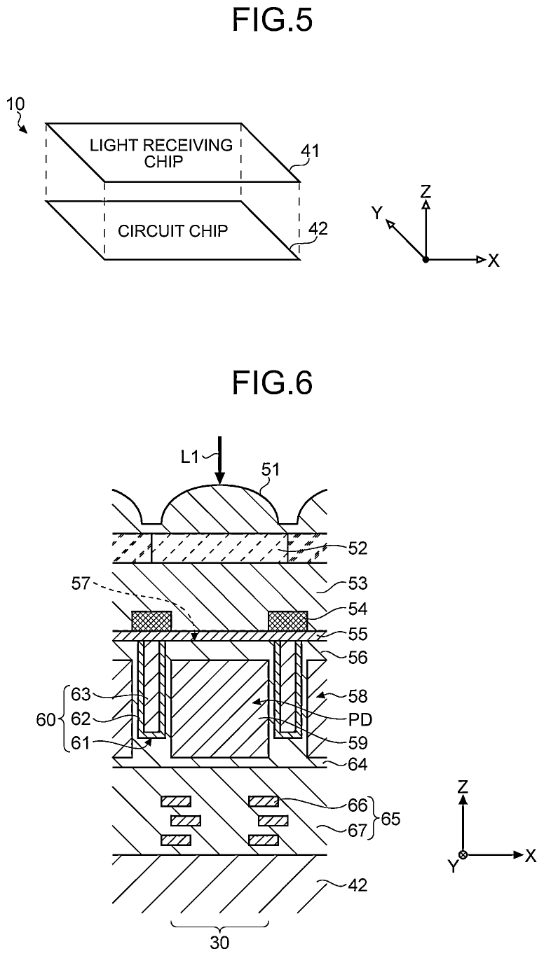

The solid-state imaging device 10 according to the present embodiment includes, for example, a stack structure in which a light receiving chip 41 (a substrate) on which a pixel array unit 21 is disposed and a circuit chip 42 (a substrate) on which a peripheral circuit is disposed are stacked (see, for example, FIG. 5). The peripheral circuit can include, for example, a vertical drive circuit 22, a column processing circuit 23, a horizontal drive circuit 24, and a system control unit 25.

The solid-state imaging device 10 further includes a signal processing unit 26 and a data storage unit 27. The signal processing unit 26 and the data storage unit 27 may be provided on the same semiconductor chip as a semiconductor chip on which the peripheral circuit is provided or may be provided on a different semiconductor chip.

The pixel array unit 21 has a configuration in which pixels 30 including photoelectric conversion elements that generate and accumulate electric charges corresponding to an amount of received light are arranged in a row direction and a column direction, that is, in a two-dimensional lattice shape in a matrix. Here, the row direction refers to an array direction of pixels in a pixel row (in the drawings, the lateral direction) and the column direction refers to an array direction of pixels in a pixel column (in the drawings, the longitudinal direction). Details of a specific circuit configuration and a specific pixel structure of the pixel 30 are explained below in detail.

In the pixel array unit 21, a pixel drive line LD is wired in the row direction for each of pixel rows and a vertical signal line VSL is wired in the column direction for each of pixel columns with respect to the matrix-like pixel array. The pixel drive line LD transmits a drive signal for performing driving at the time when a signal is read from a pixel. In FIG. 2, the pixel drive line LD is illustrated as one each wire but is not limited to the one each wire. One end of the pixel drive line LD is connected to output ends corresponding to rows of the vertical drive circuit 22.

The vertical drive circuit 22 is configured by a shift register, an address decoder, and the like, and drives the pixels of the pixel array unit 21, for example, simultaneously for all pixels or in units of rows. That is, the vertical drive circuit 22 configures a drive unit that controls operations of the pixels of the pixel array unit 21 in conjunction with the system control unit 25 that controls the vertical drive circuit 22. Although a specific configuration of the vertical drive circuit 22 is not illustrated, the vertical drive circuit 22 generally includes two scanning systems including a reading scanning system and a sweeping scanning system.

In order to read a signal from the pixels 30, the read scanning system selects and scans the pixels 30 of the pixel array unit 21 in order in units of rows. The signal read from the pixels 30 is an analog signal. The sweep scanning system performs sweep scanning on a read row, on which read scanning is performed by the read scanning system, prior to the read scanning by an exposure time.

By the sweep scanning by the sweep scanning system, unnecessary electric charges are swept out from the photoelectric conversion elements of the pixels 30 in the read row, whereby the photoelectric conversion elements are reset. Then, by sweeping out (resetting) the unnecessary electric charges in the sweeping scanning system, a so-called electronic shutter operation is performed. Here, the electronic shutter operation refers to an operation of discarding electric charges of the photoelectric conversion element and starting exposure (starting accumulation of electric charges) anew.

A signal read by the read operation by the read scanning system corresponds to an amount of light received after the immediately preceding read operation or the electronic shutter operation. Then, a period from the read timing by the immediately preceding read operation or the sweep timing by the electronic shutter operation to the read timing by the current read operation is a charge accumulation period (also referred to as exposure period) in the pixels 30.

Signals output from the pixels 30 of a pixel row selectively scanned by the vertical drive circuit 22 are input to the column processing circuit 23 through each of the vertical signal lines VSL for each of the pixel columns. The column processing circuit 23 performs, for each of the pixel columns of the pixel array unit 21, predetermined signal processing on the signals output from the pixels of the selected row through the vertical signal line VSL and temporarily holds the pixel signals after the signal processing.

Specifically, the column processing circuit 23 performs at least noise removal processing, for example, CDS (Correlated Double Sampling) processing or DDS (Double Data Sampling) processing as the signal processing. For example, fixed pattern noise specific to the pixels such as reset noise and threshold variation of amplification transistors in the pixels is removed by the CDS processing. Besides, the column processing circuit 23 includes, for example, an AD (analog-digital) conversion function and converts an analog pixel signal read from the photoelectric conversion elements into a digital signal and outputs the digital signal.

The horizontal drive circuit 24 is configured by a shift register, an address decoder, and the like and sequentially selects read circuits (hereinafter also referred to as pixel circuits) corresponding to the pixel columns of the column processing circuit 23. By the selective scanning by the horizontal drive circuit 24, pixel signals subjected to signal processing for each of the pixel circuits in the column processing circuit 23 are sequentially output.

The system control unit 25 is configured by, for example, a timing generator that generates various timing signals. The system control unit 25 performs drive control for the vertical drive circuit 22, the column processing circuit 23, the horizontal drive circuit 24, and the like on the basis of various timings generated by the timing generator.

The signal processing unit 26 has at least an arithmetic processing function and performs various kinds of signal processing such as arithmetic processing on a pixel signal output from the column processing circuit 23. In the signal processing in the signal processing unit 26, the data storage unit 27 temporarily stores data necessary for the processing.

Note that image data output from the signal processing unit 26 may be, for example, subjected to predetermined processing in the processor 13 or the like in the imaging device 1 mounted with the solid-state imaging device 10 or transmitted to the outside via a predetermined network.

### 1.3 Configuration Example of a Pixel

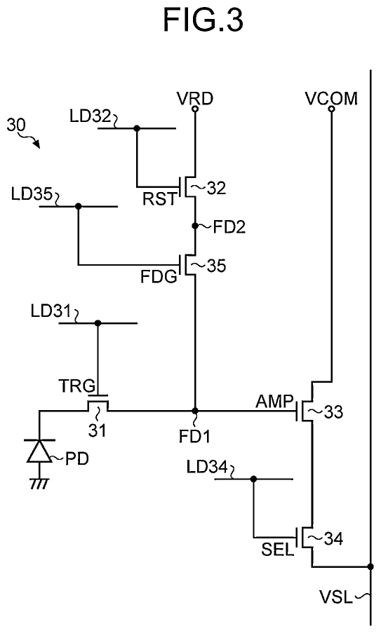

FIG. 3 is a circuit diagram illustrating a schematic configuration example of a pixel according to the present embodiment. As illustrated in FIG. 3, the pixel 30 includes, for example, a photoelectric conversion section PD, a transfer transistor 31, a first floating diffusion region FD1, a second floating diffusion region FD2, a reset transistor 32, a switching transistor 35, an amplification transistor 33, and a selection transistor 34. However, the second floating diffusion region FD2 and the switching transistor 35 may be omitted.

In this explanation, the reset transistor 32, the switching transistor 35, the amplification transistor 33, and the selection transistor 34 are also collectively referred to as pixel circuit. This pixel circuit may include at least one of the first floating diffusion region FD1, the second floating diffusion region FD2, and the transfer transistor 31.

The photoelectric conversion section PD photoelectrically converts light made incident thereon. The transfer transistor 31 transfers electric charges generated in the photoelectric conversion section PD. The first floating diffusion region FD1 and/or the second floating diffusion region FD2 accumulates the electric charges transferred by the transfer transistor 31. The switching transistor 35 controls the accumulation of the electric charges by the second floating diffusion region FD2. The amplification transistor 33 causes a pixel signal of a voltage corresponding to the electric charges accumulated in the first floating diffusion region FD1 and/or the second floating diffusion region FD2 to appear in the vertical signal line VSL. The reset transistor 32 discharges, as appropriate, the electric charges accumulated in the first floating diffusion region FD1 and/or the second floating diffusion region FD2 and the photoelectric conversion section PD. The selection transistor 34 selects the pixel 30 to be read.

The anode of the photoelectric conversion section PD is grounded and the cathode of the photoelectric conversion section PD is connected to the source of the transfer transistor 31. The drain of the transfer transistor 31 is connected to the source of the switching transistor 35 and the gate of the amplification transistor 33. This connection node configures the first floating diffusion region FD1. The reset transistor 32 and the switching transistor 35 are disposed in series between the first floating diffusion region FD1 and a vertical reset input line VRD and a node connecting the drain of the switching transistor 35 and the source of the reset transistor 32 configures the second floating diffusion region FD2.

The drain of the reset transistor 32 is connected to the vertical reset input line VRD and the source of the amplification transistor 33 is connected to a vertical current supply line VCOM. The drain of the amplification transistor 33 is connected to the source of the selection transistor 34 and the drain of the selection transistor 34 is connected to the vertical signal line VSL.

The gate of the transfer transistor 31, the gate of the reset transistor 32, the gate of the switching transistor 35, and the gate of the selection transistor 34 are connected to the vertical drive circuit 22 respectively via the transfer transistor drive line LD31, the reset transistor drive line LD32, the switching transistor drive line LD35, and the selection transistor drive line LD34 and pulse signals serving as drive signals are supplied thereto.

In such a configuration, the potential of a capacitor configured by the first floating diffusion region FD1 or the first floating diffusion region FD1 and the second floating diffusion region FD2 is determined by electric charges accumulated in the capacitor and the capacitance of the floating diffusion region FD. The capacitance of the floating diffusion region FD is determined by diffusion layer capacitance of the drain of the transfer transistor 31, source diffusion layer capacitance of the reset transistor 32, gate capacitance of the amplification transistor 33, and the like in addition to the capacitance-to-ground.

### 1.3.1 Configuration Example of a Pixel Including an FD Shared Structure

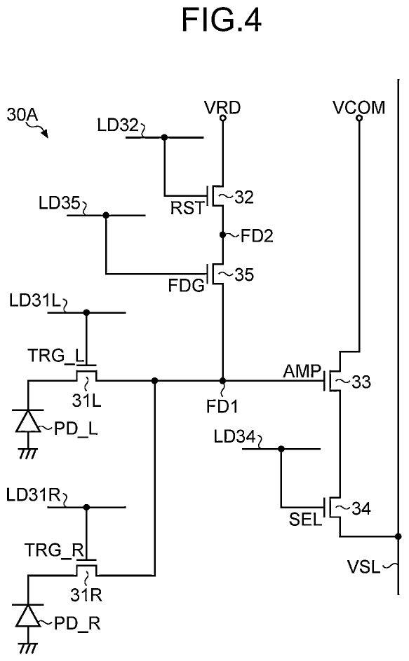

FIG. 4 is a circuit diagram illustrating a schematic configuration example of a pixel including a floating diffusion (FD) shared structure according to the present embodiment. As illustrated in FIG. 4, a pixel 30A has a structure in which a plurality of (In this example, two) photoelectric conversion sections PD_L and PL_R are connected to one floating diffusion region FD (the first floating diffusion region FD1 and the second floating diffusion region FD2) respectively via individual transfer transistors 31L and 31R in the same configuration as that of the pixel 30 explained above with reference to FIG. 3. Note that a pixel circuit shared by the pixels 30 sharing the floating diffusion region FD is connected to the floating diffusion region FD (the first floating diffusion region FD1 and the second floating diffusion region FD2).

In such a configuration, the transfer transistors 31L and 31R are configured such that different transfer transistor drive lines LD31L and LD31R are connected to gates thereof and the transfer transistors 31L and 31R are independently driven.

When an image plane phase difference pixel that enables autofocus for a subject on the basis of a signal intensity ratio of output signals respectively output from a pair of pixels is configured by, for example, a pair of pixels adjacent to each other (for example, a left pixel and a right pixel), a photoelectric conversion section PD_L configures the left pixel and a photoelectric conversion section PD_R configures the right pixel. A focal length to the subject can be calculated on the basis of the signal intensity ratio of output signals respectively output from the left pixel and the right pixel.

### 1.4 Basic Functional Example of a Unit Pixel

Next, a basic function of the pixel 30 is explained. The reset transistor 32 functions when the switching transistor 35 is in an on state and turns on/off discharge of electric charges accumulated in the first floating diffusion region FD1 and the second floating diffusion region FD2 according to a reset signal RST supplied from the vertical drive circuit 22. At that time, it is also possible to discharge electric charges accumulated in the photoelectric conversion section PD by turning on the transfer transistor 31.

When a high-level reset signal RST is input to the gate of the reset transistor 32 in a state where a high-level switching control signal FDG is input to the gate of the switching transistor 35, the first floating diffusion region FD1 and the second floating diffusion region FD2 are clamped to a voltage applied through the vertical reset input line VRD. Consequently, the electric charges accumulated in the first floating diffusion region FD1 and the second floating diffusion region FD2 are discharged (reset). At that time, by inputting a high-level transfer signal TRG to the gate of the transfer transistor 31, the electric charges accumulated in the photoelectric conversion section PD are also discharged (reset).

Note that, when a low-level reset signal RST is input to the gate of the reset transistor 32, the first floating diffusion region FD1 and the second floating diffusion region FD2 are electrically disconnected from the vertical reset input line VRD and come into a floating state.

The photoelectric conversion section PD photoelectrically converts incident light and generates electric charges corresponding to a light amount of the incident light. The generated electric charges are accumulated on the cathode side of the photoelectric conversion section PD. The transfer transistor 31 turns on/off transfer of electric charges from the photoelectric conversion section PD to the first floating diffusion region FD1 or to the first floating diffusion region FD1 and the second floating diffusion region FD2 according to the transfer control signal TRG supplied from the vertical drive circuit 22. For example, when a high-level transfer control signal TRG is input to the gate of the transfer transistor 31, the electric charges accumulated in the photoelectric conversion section PD are transferred to the first floating diffusion region FD1 or the first floating diffusion region FD1 and the second floating diffusion region FD2. On the other hand, when a low-level transfer control signal TRG is supplied to the gate of the transfer transistor 31, the transfer of the electric charges from the photoelectric conversion section PD is stopped. Note that, while the transfer transistor 31 stops transferring the electric charges to the first floating diffusion region FD1 or the first floating diffusion region FD1 and the second floating diffusion region FD2, the photoelectrically converted electric charges are accumulated in the photoelectric conversion section PD.

Each of the first floating diffusion region FD1 and the second floating diffusion region FD2 has a function of accumulating electric charges transferred from the photoelectric conversion section PD via the transfer transistor 31 and converting the electric charges into a voltage. Therefore, in the floating state in which the reset transistor 32 and/or the switching transistor 35 is turned off, the potential of each of the first floating diffusion region FD1 and the second floating diffusion region FD2 is modulated according to an amount of electric charges accumulated therein.

The amplification transistor 33 functions as an amplifier that receives, as an input signal, potential fluctuation of the first floating diffusion region FD1 or the first floating diffusion region FD1 and the second floating diffusion region FD2 connected to the gate of the amplification transistor 33. An output voltage signal of the amplification transistor 33 is output to the vertical signal line VSL via the selection transistor 34 as a pixel signal.

The selection transistor 34 turns on/off the output of the voltage signal from the amplification transistor 33 to the vertical signal line VSL according to a selection control signal SEL supplied from the vertical drive circuit 22. For example, when a high-level selection control signal SEL is input to the gate of the selection transistor 34, the voltage signal from the amplification transistor 33 is output to the vertical signal line VSL and, when a low-level selection control signal SEL is input, the output of the voltage signal to the vertical signal line VSL is stopped. Consequently, in the vertical signal line VSL to which a plurality of pixels are connected, it is possible to extract only an output of a selected pixel 30.

As explained above, the pixel 30 is driven according to the transfer control signal TRG, the reset signal RST, the switching control signal FDG, and the selection control signal SEL supplied from the vertical drive circuit 22.

### 1.5 Laminated Structure Example of the Solid-State Imaging Device

FIG. 5 is a diagram illustrating a laminated structure example of the image sensor according to the present embodiment. As illustrated in FIG. 5, the solid-state imaging device 10 has a structure in which a light receiving chip 41 and a circuit chip 42 are vertically stacked. The light receiving chip 41 has a structure in which the light receiving chip 41 and the circuit chip 42 are stacked. The light receiving chip 41 is, for example, a semiconductor chip including a pixel array unit 21 in which the photoelectric conversion sections PD are arrayed. The circuit chip 42 is, for example, a semiconductor chip in which pixel circuits are arrayed.

For bonding the light receiving chip 41 and the circuit chip 42, for example, so-called direct bonding for flattening bonding surfaces of the light receiving chip 41 and the circuit chip 42 and pasting together the bonding surfaces with an electronic force. However, not only this, but, for example, so-called Cu—Cu bonding for bonding copper (Cu) electrode pads formed on the bonding surfaces to each other, bump bonding, and the like can also be used.

In addition, the light receiving chip 41 and the circuit chip 42 are electrically connected via a connection portion such as a TSV (Through-Silicon Via), which is a through-contact piercing through a semiconductor substrate. For the connection using the TSV, for example, a so-called twin TSV method for connecting, on a chip outer surface, two TSVs, that is, a TSV provided in the light receiving chip 41 and a TSV provided from the light receiving chip 41 to the circuit chip 42, a so-called shared TSV method for connecting the light receiving chip 41 and the circuit chip 42 with a TSV piercing through the light receiving chip 41 to the circuit chip 42, and the like can be adopted.

However, when the Cu—Cu bonding or the bump bonding is used for bonding the light receiving chip 41 and the circuit chip 42, the light receiving chip 41 and the circuit chip 42 are electrically connected via a Cu—Cu bonding portion or a bump bonding portion.

### 1.6 Basic Structure Example of the Pixel

Next, a basic structure example of the pixel according to the first embodiment is explained with reference to FIG. 6 and with reference to the pixel 30 illustrated in FIG. 3. Note that a basic structure example of the pixel 30A illustrated in FIG. 4 may be the same. FIG. 6 is a sectional view illustrating a basic sectional structure example of the pixel according to the first embodiment. Note that FIG. 6 illustrates a sectional structure example of the light receiving chip 41 in which the photoelectric conversion section PD in the pixel 30 is disposed.

As illustrated in FIG. 6, in the solid-state imaging device 10, the photoelectric conversion section PD receives incident light L1 made incident from the rear surface (the upper surface in the figure) side of a semiconductor substrate 58. Above the photoelectric conversion section PD, a planarization film 53, a color filter 52, and an on-chip lens 51 are provided. Photoelectric conversion is performed on the incident light L1 made incident on the semiconductor substrate 58 from a light receiving surface 57 sequentially via the units.

As the semiconductor substrate 58, for example, a semiconductor substrate made of a group IV semiconductor configured by at least one of carbon (C), silicon (Si), germanium (Ge), and tin (Sn) or a semiconductor substrate made of a group III-V semiconductor configured by at least two of boron (B), aluminum (Al), gallium (Ga), indium (In), nitrogen (N), phosphorus (P), arsenic (As), and antimony (Sb) may be used. However, not only these, but various semiconductor substrates may be used.

The photoelectric conversion section PD may include, for example, a structure in which an N-type semiconductor region 59 is formed as a charge accumulation region that accumulates electric charges (electrons). In the photoelectric conversion section PD, the N-type semiconductor region 59 is provided in a region surrounded by P-type semiconductor regions 56 and 64 of the semiconductor substrate 58. On the front surface (lower surface) side of the semiconductor substrate 58 in the N-type semiconductor region 59, the P-type semiconductor region 64 having higher impurity concentration than that of the rear surface (upper surface) side is provided. That is, the photoelectric conversion section PD has an HAD (Hole-Accumulation Diode) structure. The P-type semiconductor regions 56 and 64 are provided to suppress occurrence of a dark current on interfaces with the upper surface side and the lower surface side of the N-type semiconductor region 59.

Pixel separation sections 60 that electrically separate the plurality of pixels 30 are provided inside the semiconductor substrate 58. The photoelectric conversion sections PD is provided in a region divided by the pixel separation sections 60. In the figure, when the solid-state imaging device 10 is viewed from the upper surface side, for example, the pixel separation sections 60 are provided in a lattice shape to be interposed between the plurality of pixels 30 and the photoelectric conversion section PD is disposed the region divided by the pixel separation section 60.

In the photoelectric conversion sections PD, the anodes are grounded. In the solid-state imaging device 10, signal charges (for example, electrons) accumulated by the photoelectric conversion sections PD are read via a not-illustrated transfer transistor 31 (see FIG. 3) or the like and output to a not-illustrated vertical signal line VSL (see FIG. 3) as electric signals.

A wiring layer 65 is provided on the front surface (the lower surface) of the semiconductor substrate 58 on the opposite side to the rear surface (the upper surface) on which the units such as a light blocking film 54, the planarization film 53, the color filter 52, and the on-chip lens 51 are provided.

The wiring layer 65 is configured by a wire 66, an insulating layer 67, and a through-electrode (not illustrated). An electric signal from the light receiving chip 41 is transmitted to the circuit chip 42 via the wire 66 and the through-electrode (not illustrated). Similarly, the substrate potential of the light receiving chip 41 is also applied from the circuit chip 42 via the wire 66 and the through-electrode (not illustrated).

For example, the circuit chip 42 illustrated in FIG. 5 is bonded to the surface of the wiring layer 65 on the opposite side to the side on which the photoelectric conversion section PD is provided.

The light blocking film 54 is provided on the rear surface (the upper surface in the figure) side of the semiconductor substrate 58 and blocks a part of the incident light L1 traveling from above the semiconductor substrate 58 toward the rear surface of the semiconductor substrate 58.

The light blocking film 54 is provided above the pixel separation section 60 provided inside the semiconductor substrate 58. Here, the light blocking film 54 is provided to protrude in a convex shape via an insulating film 55 such as a silicon oxide film on the rear surface (the upper surface) of the semiconductor substrate 58. In contrast, above the photoelectric conversion section PD provided inside the semiconductor substrate 58, the light blocking film 54 is not provided and a space is open such that the incident light L1 is made incident on the photoelectric conversion section PD.

That is, when the solid-state imaging device 10 is viewed from the upper surface side in the figure, the planar shape of the light blocking film 54 is a lattice shape and an opening through which the incident light L1 passes to the light receiving surface 57 is formed.

The light blocking film 54 is formed of a light blocking material that blocks light. For example, the light blocking film 54 is formed by sequentially stacking a titanium (Ti) film and a tungsten (W) film. Besides, the light blocking film 54 can be formed by, for example, sequentially stacking a titanium nitride (TiN) film and a tungsten (W) film.

The light blocking film 54 is covered with the planarization film 53. The planarization film 53 is formed using an insulating material that transmits light. As the insulating material, for example, silicon oxide (SiO₂) or the like can be used.

The pixel separation section 60 includes, for example, a groove section 61, a fixed charge film 62, and an insulating film 63 and is provided on the rear surface (upper surface) side of the semiconductor substrate 58 to cover the groove section 61 that divides the plurality of pixels 30.

Specifically, the fixed charge film 62 is provided to cover, at constant thickness, the inner side surface of the groove section 61 formed on the rear surface (the upper surface) side in the semiconductor substrate 58. Then, the insulating film 63 is provided (filled) to embed the inside of the groove section 61 covered with the fixed charge film 62.

Here, the fixed charge film 62 is formed using a high dielectric having a negative fixed charge such that a positive charge (hole) accumulation region is formed in an interface portion with the semiconductor substrate 58 and occurrence of a dark current is suppressed. Since the fixed charge film 62 has a negative fixed charge, an electric field is applied to the interface with the semiconductor substrate 58 by the negative fixed charge and a positive charge (hole) accumulation region is formed.

The fixed charge film 62 can be formed of, for example, a hafnium oxide film (HfO₂ film). Besides, the fixed charge film 62 can be formed to contain at least one of oxides such as hafnium, zirconium, aluminum, tantalum, titanium, magnesium, yttrium, and lanthanoid elements.

Note that the pixel separation section 60 is not limited to the configuration explained above and can be variously modified. For example, by using a reflective film that reflects light such as a tungsten (W) film instead of the insulating film 63, it is possible to form the pixel separation section 60 in a light reflection structure. Consequently, the incident light L1 entering the photoelectric conversion section PD can be reflected by the pixel separation section 60. Therefore, the optical path length of the incident light L1 in the photoelectric conversion section PD can be increased. In addition, by forming the pixel separation section 60 in the light reflection structure, it is possible to reduce leakage of light to adjacent pixels. Therefore, it is also possible to further improve image quality, distance measurement accuracy, and the like. Note that, when a metal material such as tungsten (W) is used as the material of the reflective film, an insulating film such as a silicon oxide film may be provided in the groove section 61 instead of the fixed charge film 62.

The configuration in which the pixel separation section 60 is formed in the light reflection structure is not limited to the configuration using the reflective film and can be implemented by, for example, embedding a material having a higher refractive index or a lower refractive index than the semiconductor substrate 58 in the groove section 61.

Further, FIG. 6 illustrates the pixel separation section 60 having a so-called RDTI (Reverse Deep Trench Isolation) structure in which the pixel separation section 60 is provided in the groove section 61 formed from the rear surface (the upper surface) side of the semiconductor substrate 58. However, not only this, but it is possible to adopt, for example, the pixel separation section 60 having various structures such as a so-called DTI (Deep Trench Isolation) structure in which the pixel separation section 60 is provided in a groove section formed from the front surface (the lower surface) side of the semiconductor substrate 58 and a so-called FTI (Full Trench Isolation) structure in which the pixel separation section 60 is provided in a groove section formed to pierce through the front and rear surfaces of the semiconductor substrate 58.

### 1.7 Planar Layout Example of an Image Plane Phase Difference Pixel

Subsequently, a planar layout example of a pixel (hereinafter also referred to as image plane phase difference pixel) configured as a pixel pair capable of acquiring an image plane phase difference is explained on the basis of the basic structure example of the pixel 30 illustrated in FIG. 6.

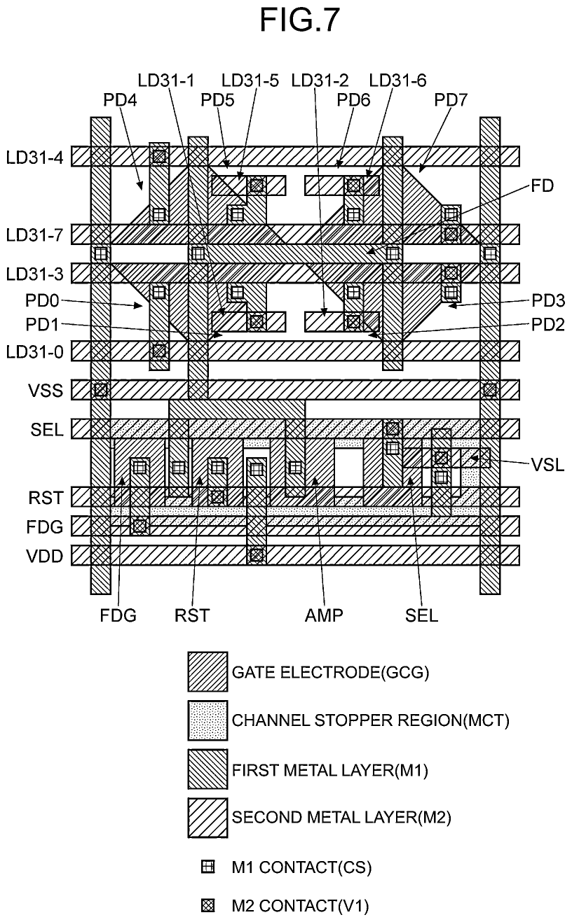

FIG. 7 is a schematic plan view illustrating a planar layout example of the image plane phase difference pixel according to the present embodiment. Note that FIG. 7 illustrates a case including a so-called eight-pixel shared structure in which eight pixels 30 share one floating diffusion region FD. However, the present embodiment is not limited to the eight-pixel shared structure and may have a structure in which two or more pixels 30 share one floating diffusion region FD or may have a structure in which the pixels 30 have individual FDs (that is, do not have an FD shared structure). FIG. 7 illustrates a case in which a pixel circuit including the reset transistor 32, the switching transistor 35, the amplification transistor 33, and the selection transistor 34 (and the floating diffusion region FD) is provided on the semiconductor substrate 58 provided with eight photoelectric conversion sections PD0 to PD7 and eight transfer transistors 31. However, not only this configuration, but, for example, as explained with reference to FIG. 5 and the like, the pixel circuit may be provided on the circuit chip 42 side bonded to the semiconductor substrate 58 (the light receiving chip 41).

As illustrated in FIG. 7, in the present embodiment, the eight photoelectric conversion sections PD0 to PD7 are arrayed in two rows and four columns on a semiconductor substrate 58 (see FIG. 6). In the following explanation, for convenience of explanation, the pixels 30 respectively including the photoelectric conversion sections PD0 to PD7 are referred to as pixels 30-0 to 30-7. The transfer transistors 31 of the respective pixels 30-0 to 30-7 are referred to as transfer transistors 31-0 to 31-7.

The pixels 30-0, 30-1, 30-4, and 30-5 are arrayed in two rows and two columns in the left half in the array of two rows and four columns. The remaining pixels 30-2, 30-3, 30-6, and 30-7 are arrayed in two rows and two columns in the right side half of the array of two rows and four columns. The transfer transistors 31-0, 31-1, 31-4, and 31-5 of the pixels 30-0, 30-1, 30-4, and 30-5 arrayed in the left side half of the array are provided at corners facing one another in the respective pixels 30-0, 30-1, 30-4, and 30-5. Similarly, the transfer transistors 31-2, 31-3, 31-6, and 31-7 of the pixels 30-2, 30-3, 30-6, and 30-7 arrayed in the right side half of the array are provided at corners facing one another in the respective pixels 30-2, 30-3, 30-6, and 30-7.

Among the pixels 30-0 to 30-7 arrayed as explained above, the pixel 30-0 and the pixel 30-1, the pixel 30-2 and the pixel 30-3, the pixel 30-4 and the pixel 30-5, and the pixel 30-6 and the pixel 30-7 respectively configure sets of image plane phase difference pixels. However, not only this, but the pixels 30-0, 30-2, 30-4, and 30-6, and the pixels 30-1 and 30-3, the pixel 30-5, and the pixel 30-7 may configure one image plane phase difference pixel or the pixels 30-0 and 30-4 and the pixels 30-1 and 30-5 may configure one image plane phase difference pixel, and the pixels 30-2 and 30-6 and the pixel 30-3 and the pixel 30-7 may configure one image plane phase difference pixel. In these cases, the pixels 30-0, 30-2, 30-4, and 30-6 operate as the left pixels of the image plane phase difference pixels and the pixels 30-1, 30-3, 30-5, and 30-7 operate as the right pixels of the image plane phase difference pixels. This makes it possible to implement autofocus based on an image plane phase difference in the left-right direction.

Note that the pixel 30-0 and the pixel 30-4, the pixel 30-1 and the pixel 30-5, the pixel 30-2 and the pixel 30-6, and the pixel 30-3 and the pixel 30-7 may respectively configure pixel pairs to configure one or more image plane phase difference pixels. In that case, the pixels 30-0, 30-1, 30-2, and 30-3 operate as the lower pixels of the image plane phase difference pixels and the pixels 30-4, 30-5, 30-6, and 30-7 operate as the upper pixels of the image plane phase difference pixels. This makes it possible to implement autofocus based on an image plane phase difference in the vertical direction.

However, not only this, but, for example, autofocus may be implemented on the basis of both of the image plane phase difference in the left-right direction and the image plane phase difference in the up-down direction. In that case, the pixel 30-0 operates as the left pixel and the lower pixel, the pixel 30-1 operates as the right pixel and the lower pixel, the pixel 30-2 operates as the left pixel and the lower pixel, the pixel 30-3 operates as the right pixel and the lower pixel, the pixel 30-4 operates as the left pixel and the upper pixel, the pixel 30-5 operates as the right pixel and the upper pixel, the pixel 30-6 operates as the left pixel and the upper pixel, and the pixel 30-7 operates as the right pixel and the upper pixel.

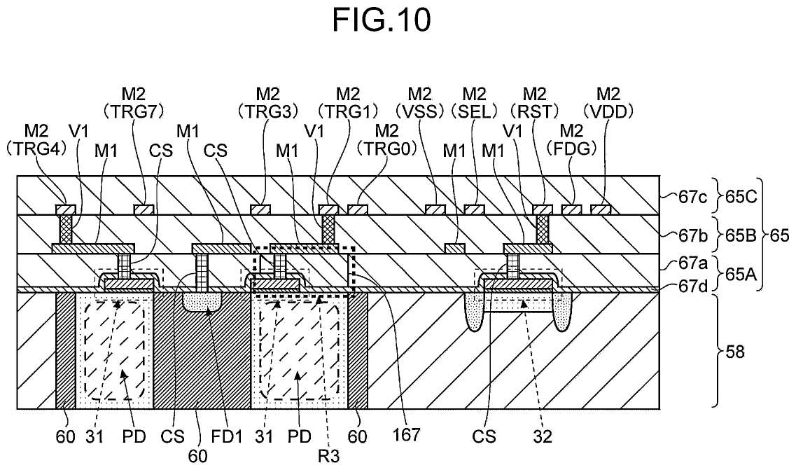

Gate electrodes of the transfer transistors 31-0 to 31-7 of the pixels 30-0 to 30-7 and various transistors configuring the pixel circuit are connected to a metal wire (hereinafter also referred to as first metal layer) M1 of a first layer provided on an interlayer insulating film of the first layer via a via wire (hereinafter also referred to as M1 contact) CS piercing through, for example, the interlayer insulating film of the first layer (a part of the insulating layer 67 in FIG. 6, see, for example, an interlayer insulating film 67a in FIG. 10) provided on an element forming surface of the semiconductor substrate 58. The first metal layer M1 to which the gate electrodes of the transistors are connected is connected to a metal wire (hereinafter also referred to as second metal layer) M2 of a second layer provided on an interlayer insulating film of the second layer via a via wire (hereinafter also referred to as M2 contact) V1 piercing through the interlayer insulating film of the second layer (a part of the insulating layer 67 in FIG. 6, see, for example, an interlayer insulating film 67b in FIG. 10) provided on the interlayer insulating film of the first layer.

In such a configuration, wires (the M1 contact CS, the first metal layer M1, the M2 contact V1, and the second metal layer M2) connected to the gate electrodes of the respective transfer transistors 31-0 to 31-7 configure parts of respective transfer transistor drive lines LD31-0 to LD31-7.

Note that the first metal layer M1 may be provided to mainly extend, for example, in the column direction (the longitudinal direction in figure) and the second metal layer M2 may be provided to mainly extend, for example, in the row direction (the lateral direction in the figure). In this example, parts of the first metal layer M1 respectively connected to the drains of the transfer transistors 31-0 to 31-7, the source of the switching transistor 35 (or the reset transistor 32), and the gate electrode of the amplification transistor 33 may configure the floating diffusion region FD.

### 1.8 Basic Operation Example of the Image Plane Phase Difference Pixel

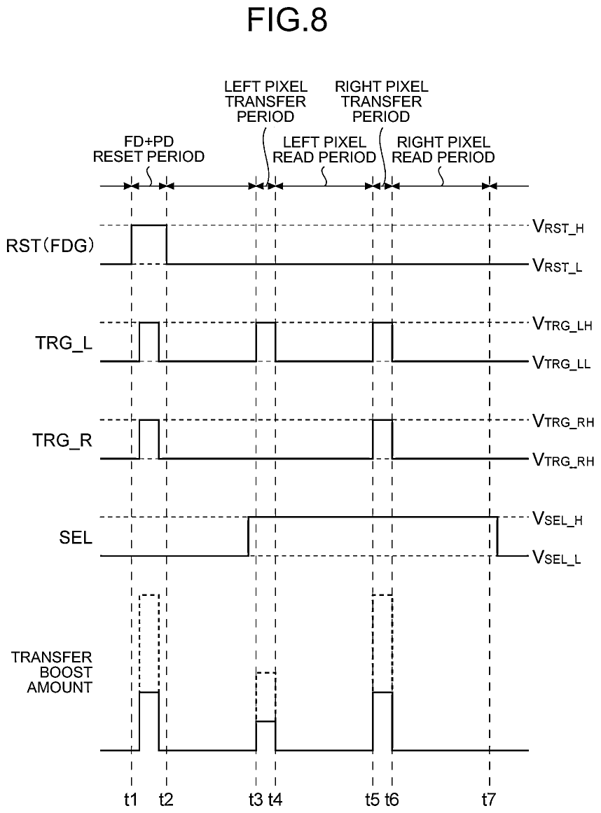

Next, a basic operation example of the image plane phase difference pixel illustrated in FIG. 7 is explained with reference to FIG. 8. FIG. 8 is a timing chart illustrating a basic operation example of the image plane phase difference pixel according to the present embodiment. Note that, in the following explanation, for simplicity, a case in which the pixels 30-0, 30-2, 30-4, and 30-6 operate as left pixels 30L and the pixels 30-1, 30-3, 30-5, and 30-7 operate as right pixels 30R is illustrated. However, for each of the left pixels and the right pixels, the number of pixels simultaneously read may be one or more.

As illustrated in FIG. 8, in the present operation example, during a period (FD+PD reset period) of timings t1 and t2 when a reset signal RST (and a switching control signal FDG) is at a high level V_{RST_H}, a high-level transfer control signals V_{TRG_LH} and V_{TRG_RH} are applied to the transfer transistors 31L of the left pixels 30L and the transfer transistors 31R of the right pixels 30R and the transfer transistors 31L and the transfer transistors 31R are simultaneously turned on. Consequently, electric charges accumulated in the first floating diffusion region FD1 and the second floating diffusion region FD2 and the photoelectric conversion sections PD_L and PD_R are discharged (reset) via the switching transistor 35 and the reset transistor 32.

Thereafter, a high-level selection control signal V_{SEL_H} is applied to the selection transistor 34 and the selection transistor 34 is turned on at timing before timing t3, whereby the left pixel 30L and the right pixel 30R to be read are selected.

In a period in which the selection transistor 34 is set in the on state, for example, read from the left pixel 30L is executed first and read from the right pixel 30R is executed next. A pixel that is read first (for example, the left pixel 30L) is also referred to as lookahead pixel and a pixel that is read later (for example, the right pixel 30R) is also referred to as lookbehind pixel.

Therefore, in the period in which the selection transistor 34 is set in the on state, a high-level transfer control signal V_{TRG_LH} is applied to the transfer transistor 31L of the left pixel 30L and the transfer transistor 31L is turned on a period of timings t3 to t4 (a left pixel transfer period). Consequently, electric charges accumulated in the photoelectric conversion section PD_L of the left pixel 30L are transferred to the first floating diffusion region FD1 (and the second floating diffusion region FD2) and a voltage corresponding to the accumulated electric charges appears in the vertical signal line VSL connected to the source of the amplification transistor 33 via the selection transistor 34.

In a period of the next timings t4 to t5 (a left pixel read period), the voltage appearing in the vertical signal line VSL is read by the column processing circuit 23 as a pixel signal of the left pixel 30L.

Next, in a period in which the selection transistor 34 is set in the on state, the high-level transfer control signal V_{TRG_RH} is applied to the transfer transistor 31R of the right pixel 30R and the transfer transistor 31R is turned on in a period of timings t5 to t6 (a right pixel transfer period). Consequently, electric charges accumulated in the photoelectric conversion section PD_L of the left pixel 30L are transferred to the first floating diffusion region FD1 (and the second floating diffusion region FD2) and a voltage corresponding to the accumulated electric charges appears in the vertical signal line VSL connected to the source of the amplification transistor 33 via the selection transistor 34. At that time, the transfer transistor 31L of the left pixel 30L is also turned on, whereby it is possible to increase a transfer boost amount (explained below) from the photoelectric conversion section PD_R of the right pixel 30R to the floating diffusion region FD (FD1 or FD1+FD2). Therefore, it is possible to improve reading efficiency of electric charges accumulated in the photoelectric conversion section PD_R.

In a period from the next timings t6 to t7 (a right pixel read period), the voltage appearing in the vertical signal line VSL is read by the column processing circuit 23 as a pixel signal of the right pixel 30R.

Thereafter, at timing t7 and subsequent timing, a low-level selection control signal V_{SEL}_is applied to the selection transistor 34 and the selection transistor 34 is turned off, whereby the selection of the left pixel 30L and the right pixel 30R to be read is released.

### 1.9 Problems in the Image Plane Phase Difference Pixel

Conventionally, in a solid-state imaging device adopting image plane phase difference autofocus, in order to reduce variations in output signals between a pair of pixels (for example, a right pixel and a left pixel) configuring an image plane phase difference pixel, force (also referred to as transfer boost amount) by potential acting in a direction of feeding electric charges from photoelectric conversion sections of pixels to floating diffusion regions is designed to be approximately the same between the pair of pixels.

However, according to further miniaturization of pixels in recent years, problems such as a decrease in flexibility of a wiring layer, difficulty in controlling parasitic capacitance from a transfer transistor to a floating diffusion region, a decrease in an effective light receiving area, and a decrease in conversion efficiency due to securing of a transfer boost amount occur. It has been becoming difficult to adjust the difference in a transfer boost amount between a pair of pixels to the same degree.

At the time of driving (hereinafter driving is also referred to as LCD (Low Conversion Gain) driving) with low conversion efficiency, there is also a problem in that a transfer boost amount at the time of read increases according to an increase in the number of added pixels, and unnecessary electric charges leak into the floating diffusion region. As a result, white spot-like noise appears in an image (hereinafter also referred to as FD white point degradation), leading to deterioration of image quality.

Specifically, as illustrated by a broken line in a lower part of FIG. 8, in the image plane phase difference pixel having the FD shared structure, when a reading method for simultaneously turning on the transfer transistors 31 (for example, the transfer transistor 31L) of the lookahead pixel (for example, the right pixel 30R) when reading the lookbehind pixel (for example, the left pixel 30L) is adopted, the number of transfer transistors 31 simultaneously being turned on increases. Consequently, a transfer boost amount at the time when the lookbehind pixel is read significantly increases than a transfer boost amount at the time when the lookahead pixel is read. As a result, the electric field of the floating diffusion region FD becomes strong, and unnecessary charges leak into the floating diffusion region FD, and FD white point deterioration occurs.

Therefore, in the present embodiment, it is possible to reduce variations in output signals between the pair of pixels (for example, the right pixel and the left pixel) configuring the image plane phase difference pixel by enabling adjustment of the transfer boost amount even if miniaturization of the pixels advances. By making it possible to reduce variations in output signals between the pair of pixels, it is possible to suppress deterioration in image quality. Therefore, for example, it is possible to prevent a time required for focus adjustment from becoming redundant.

Note that, in one aspect of the present embodiment, since the transfer boost amount can be adjusted, it is also possible to suppress a decrease in conversion efficiency. In one aspect of the present embodiment, since the transfer boost amount can be adjusted, it is also possible to alleviate the FD white point deterioration at the time of inter-pixel reading.

### 1.10 Example of an Adjustment Method for a Transfer Boost Amount

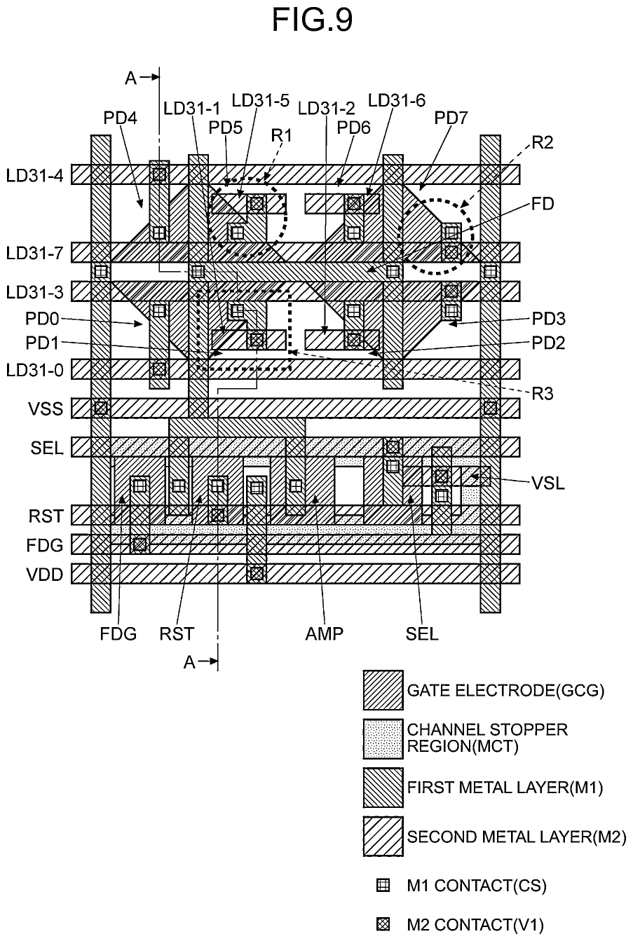

Subsequently, an adjustment method for a transfer boost amount according to the present embodiment is explained with reference to FIG. 9 with some examples.

In the present embodiment, the following three methods are exemplified as the adjustment method of the transfer boost amount.
First method: a method of reducing a wiring area of a transfer gate wire (transfer transistor drive line LD31R) of a lookbehind pixel (in this example, the right pixel) (see a region R1 in FIG. 9)
Second method: a method of increasing a space between the transfer gate line (the transfer transistor drive line LD31R) of the lookbehind pixel (in this example, the right pixel) and the floating diffusion region FD (see a region R2 in FIG. 9)
Third method: a method of locally reducing a dielectric constant of an interlayer insulating film material around the lookbehind pixel (In this example, the right pixel) (see a region R3 in FIG. 9)

### 1.10.1 First Method

First, the first method is explained in detail with reference to FIG. 9. As illustrated in the region R1 in FIG. 9, in the first method, a wiring area (for example, an area of the transfer transistor drive line LD31-5 in the first metal layer M1 and the second metal layer M2) of the right pixel 30-5, which is one of lookbehind pixels, is designed. For example, a wiring area of the right pixel 30-5, which is one of the lookbehind pixels, is designed to be smaller than a wiring area (for example, an area of the transfer transistor drive line LD31-4 in the first metal layer M1 and the second metal layer M2) of the left pixel (for example, the left pixel 30-4), which is the lookahead pixel.

Note that the wiring area being small may mean that a wiring area of the transfer transistor drive line LD31 in the first metal layer M1 and/or the second metal layer M2 is small or may mean that an area of the transfer transistor drive line LD31 facing the floating diffusion region FD is small.

By reducing the wiring area of the lookbehind pixel in this way, a wiring area facing the floating diffusion region FD can be reduced. Therefore, coupling capacitance can be reduced by suppressing coupling between a wire of the lookbehind pixel and the floating diffusion region FD. Consequently, since it is possible to perform adjustment to suppress a transfer boost amount of the lookbehind pixel, which increases when the transfer transistor 31 is turned on in the same period as a period when the transfer transistor 31 of the lookahead pixel is turned on, it is possible to reduce variations in output signals between the pair of pixels (for example, the right pixel and the left pixel) configuring the image plane phase difference pixel. As a result, deterioration in image quality can be suppressed.

In the first method, since it is possible to perform adjustment to suppress the transfer boost amount of the lookbehind pixel, it is also possible to achieve effects of, for example, suppressing a decrease in conversion efficiency and alleviating FD white point deterioration at the time of inter-pixel reading.

Note that, in this example, the explanation is made focusing on the pixel pair of the right pixel 30-5 and the left pixel 30-4. However, not only this, but the first method may be applied to another pixel pair. Further, the first method may be implemented in combination with other methods.

### 1.10.2 Second Method

Next, the second method is explained in detail with reference to FIG. 9. As illustrated in the region R2 in FIG. 9, in the second method, the distance from a wire (for example, the transfer transistor drive line LD31-7 in the first metal layer M1 and the second metal layer M2) of the right pixel 30-7, which is one of the lookbehind pixels, to the floating diffusion region FD is designed to be long. For example, the distance from a wire of the right pixel 30-5, which is one of the lookbehind pixels, to the floating diffusion region FD is designed to be longer than the distance from a wire (for example, the transfer transistor drive line LD31-6 in the first metal layer M1 and the second metal layer M2) of the left pixel (for example, the left pixel 30-6), which is the lookahead pixel, to the floating diffusion region FD.

Note that the distance from the transfer transistor drive line LD31 to the floating diffusion region FD may be variously modified to, for example, a shortest distance from the transfer transistor drive line LD31 to the floating diffusion region FD and an average distance in a region where the transfer transistor drive line LD31 and the floating diffusion region FD face each other.

By increasing the distance from the wire of the lookbehind pixel to the floating diffusion region FD, it is possible to suppress coupling between the wire of the lookbehind pixel and the floating diffusion region FD to reduce coupling capacitance. Consequently, as in the first method, it is possible to perform adjustment to suppress the transfer boost amount of the lookbehind pixel. Therefore, it is possible to reduce variations in output signals between the pair of pixels (for example, the right pixel and the left pixel) configuring the image plane phase difference pixel. As a result, it is possible to suppress deterioration in image quality.

In the second method, as in the first method, it is possible to perform adjustment to suppress the transfer boost amount of the lookbehind pixel. Therefore, it is also possible to achieve effects of, for example, suppressing a decrease in conversion efficiency and alleviating FD white point deterioration at the time of inter-pixel reading.

Note that, in this example, the explanation is made focusing on the pixel pair of the right pixel 30-7 and the left pixel 30-6. However, not only this, but the second method may be applied to another pixel pair. Further, the second method may be implemented in combination with other methods.

### 1.10.3 Third Method

Next, the third method is explained in detail with reference to FIG. 9 and FIG. 10. FIG. 10 is a vertical sectional view illustrating a sectional structure example of the image plane phase difference pixel taken along line A-A in FIG. 9. Note that “perpendicular” referred to herein may mean perpendicular to an element forming surface of the semiconductor substrate 58. Furthermore, the line A-A is set to pass from the photoelectric conversion section PD4 of the pixel 30-4 to the reset transistor 32 via the photoelectric conversion section PD1 of the pixel 30-1.

In the sectional structure example illustrated in FIG. 10, the semiconductor substrate 58 is divided into a plurality of pixel regions by the pixel separation sections 60 and the photoelectric conversion sections PD are formed in pixel regions. A pixel circuit including the transfer transistor 31 and the reset transistor 32 is provided on the element forming surface of the semiconductor substrate 58.

The element forming surface on which the pixel circuit is provided is covered with, for example, an insulating film 67d including a sidewall provided on gate electrode side surfaces of transistors. An interlayer insulating film 67a of a first layer is provided on the insulating film 67d.

The first metal layer M1 including a part of the pixel drive line LD is provided on the upper surface of the interlayer insulating film 67a. The first metal layer M1 is connected to gate electrodes, sources/drains, and the like of the transistors via the M1 contact CS piercing through the interlayer insulating film 67a and the insulating film 67d.

On the interlayer insulating film 67a, an interlayer insulating film 67b of a second layer is provided to fill the first metal layer M1. The second metal layer M2 including a part of the pixel drive line LD is provided on the upper surface of the interlayer insulating film 67b. The second metal layer M2 is connected to the first metal layer M1 as appropriate via the M2 contact V1 piercing through the interlayer insulating film 67b. An interlayer insulating film 67c of a third layer is provided on the interlayer insulating film 67b provided with the second metal layer M2 to cover the second metal layer M2.

Here, as illustrated in the region R3 illustrated in FIG. 9 and FIG. 10, in the third method, at least a part of an insulating film around the wire (for example, the transfer transistor drive line LD31-1 in the first metal layer M1 and the second metal layer M2) of the right pixel 30-1, which is one of the lookbehind pixels, is replaced with an insulating film having a low dielectric constant. In the example illustrated in FIG. 10, at least a region around the M1 contact CS connecting the gate electrode of the transfer transistor 31-1 and the first metal layer M1 and under the first metal layer M1 connected to the M1 contact CS in the interlayer insulating film 67a are locally replaced with an insulating film 167 having a dielectric constant lower than that of the interlayer insulating film 67a.

By replacing at least a part of the insulating film around the wire of the lookbehind pixel with the insulating film 167 having the low dielectric constant in this way, it is possible to suppress coupling between the wire of the lookbehind pixel and the floating diffusion region FD to reduce coupling capacitance. Consequently, as in the first and second methods, it is possible to perform adjustment to suppress the transfer boost amount of the lookbehind pixel. Therefore, it is possible to reduce variations in output signals between the pair of pixels (for example, the right pixel and the left pixel) configuring the image plane phase difference pixel. As a result, it is possible to suppress deterioration in image quality.

In the third method, as in the first and second methods, it is possible to perform adjustment to suppress the transfer boost amount of the lookbehind pixel. Therefore, it is also possible to achieve effects of, for example, suppressing a decrease in conversion efficiency and alleviating FD white point deterioration at the time of inter-pixel reading.

Note that, in this example, the explanation is made focusing on the right pixel 30-1. However, not only this, but the second method may be applied to the other right pixel 30R. Further, the third method may be implemented in combination with other methods.

### 1.10.3.1 Example of a Manufacturing Method

Here, a method of manufacturing a solid-state imaging device having a structure in which a dielectric constant of the interlayer insulating film material around the lookbehind pixel is locally lowered, which is illustrated as the third method, is explained with an example.

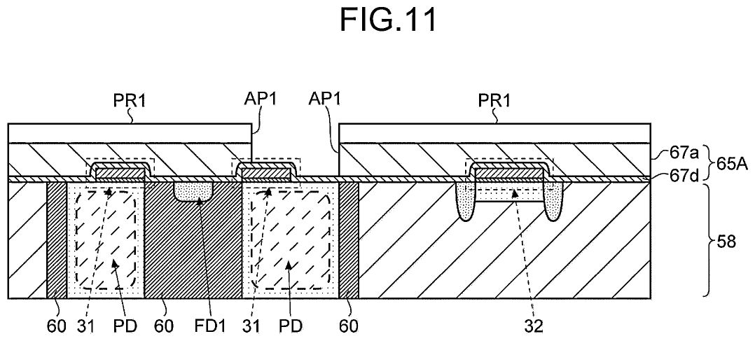

FIG. 11 to FIG. 15 are process sectional views for explaining an example of a manufacturing method according to the present embodiment. Note that FIG. 11 to FIG. 15 are vertical sectional views taken along a line corresponding to the line A-A illustrated in FIG. 10.

First, as illustrated in FIG. 11, in this manufacturing method, by forming the pixel separation section 60 on the semiconductor substrate 58, the semiconductor substrate 58 is divided into a plurality of pixel regions and the photoelectric conversion sections PD are formed in the pixel regions. Note that, in the formation of the pixel separation section 60, for example, lithography and etching techniques may be used to form the groove section (which may pierce) 61 in which the pixel separation section 60 is formed. For formation of the fixed charge film 62 and the insulating film 63 in the groove section 61, for example, a film forming technique such as a CVD (Chemical Vapor Deposition) method or sputtering may be used.

Subsequently, for example, a pixel circuit including the transfer transistor 31, the reset transistor 32, and the floating diffusion region FD1 is formed on the element forming surface of the semiconductor substrate 58 through a normal element formation process. Note that, for example, an N-type diffusion region for element formation may be provided on the element forming surface side of the pixel separation section 60 in the semiconductor substrate 58 and the floating diffusion region FD1 and other pixel circuits may be formed in the N-type diffusion region.

Subsequently, for example, the insulating film 67d and the interlayer insulating film 67a are sequentially formed on the element forming surface on which the pixel circuit is formed by using a film forming technique such as a CVD method or sputtering. The insulating film 67d and the interlayer insulating film 67a may be, for example, insulating films such as a silicon oxide film (SiO₂) and a silicon nitride film (SiN).

Subsequently, a mask PR1 having an opening AP1 is formed on the interlayer insulating film 67a, for example, by using a lithography technique. The opening AP1 may be an opening that exposes at least a part of the periphery of the region where the wire of the lookbehind pixel is formed. In the example illustrated in FIG. 11, the opening AP1 may be an opening that exposes at least a region around a region where the M1 contact CS that connects the gate electrode of the transfer transistor 31-1 and the first metal layer M1 is formed and under a region where the first metal layer M1 connected to the M1 contact CS is formed in the interlayer insulating film 67a. Note that the mask PR1 may be a resist film or may be a hard mask such as a silicon oxide film.

Subsequently, the interlayer insulating film 67a exposed from the opening AP1 is removed and an opening AP2 is formed, for example, by using anisotropic dry etching such as RIE (Reactive Ion Etching) or wet etching.

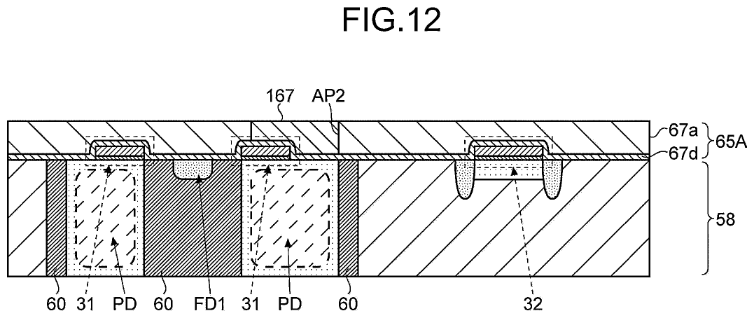

Next, after the mask PR1 is removed, as illustrated in FIG. 12, the insulating film 167 is formed in the opening AP2 formed in the interlayer insulating film 67a by depositing an insulating material having a dielectric constant lower than that of the interlayer insulating film 67a, for example, using a film forming technique such as a CVD method or sputtering. Note that the insulating material deposited on the interlayer insulating film 67a may be removed using, for example, CMP (Chemical Mechanical Polishing).

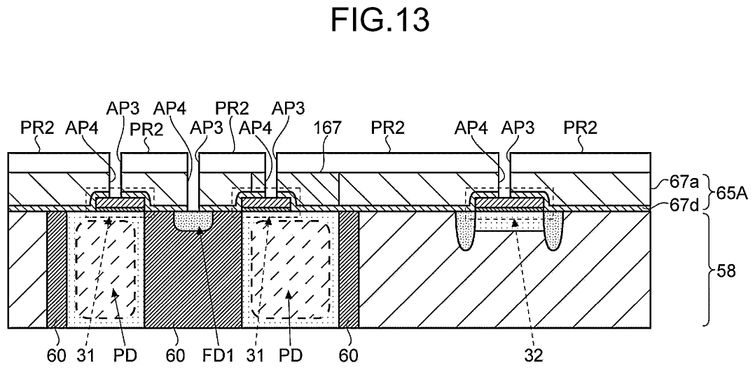

Next, as illustrated in FIG. 13, a mask PR2 having an opening AP3 is formed on the interlayer insulating film 67a and the insulating film 167, for example, by using a lithography technique. The opening AP3 may be an opening that exposes a region where the M1 contact CS connected to the gate electrodes and the sources/drains of the transistors is formed. In addition, the opening AP3 may expose a region where the floating diffusion region FD1 (or FD1 and FD2) in the upper layer of the semiconductor substrate 58 is formed. Note that the mask PR2 may be a resist film or may be a hard mask such as a silicon oxide film.

Subsequently, the interlayer insulating film 67a, the insulating film 167, and the insulating film 67d exposed from the opening AP3 are removed and an opening AP4 is formed, for example, by using anisotropic dry etching such as RIE (Reactive Ion Etching).

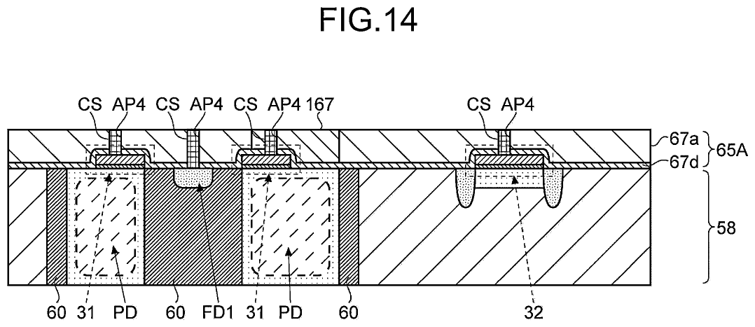

Next, after the mask PR2 is removed, as illustrated in FIG. 14, the floating diffusion region FD1 (or FD1 and FD2) is formed on the semiconductor substrate 58, for example, by using an ion implantation method. Subsequently, the M1 contact CS connected to the gate electrodes and the sources/drains of the transistors and the floating diffusion region FD1 (or FD1 and FD2) is formed by embedding a conductive material in the opening AP4 using a film forming technique such as CVD or sputtering.

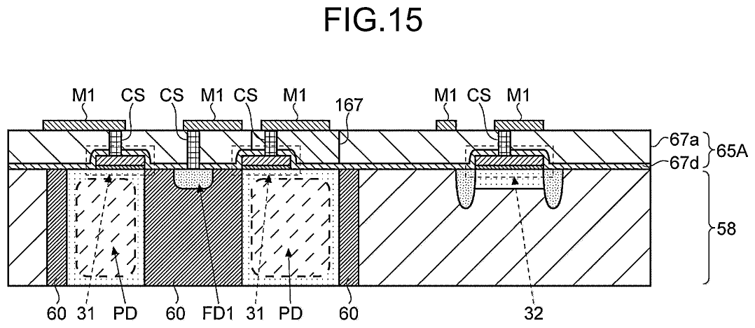

Next, as illustrated in FIG. 15, the first metal layer M1 connected to the M1 contact CS is formed on the interlayer insulating film 67a and the insulating film 167, for example, by using a lift-off method or the like.

Thereafter, the interlayer insulating film 67b, the M2 contact V1, the second metal layer M2, and the interlayer insulating film 67c are sequentially formed on the interlayer insulating film 67a on which the first metal layer M1 is formed, whereby the solid-state imaging device having the sectional structure illustrated in FIG. 10 is manufactured.

Note that the manufacturing method explained above is merely an example and may be variously modified.

### 1.10.3.2 Modification of a Third Method

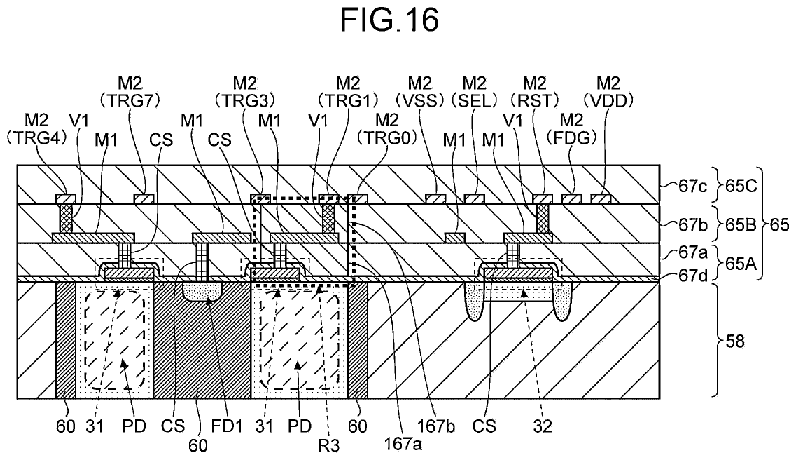

In the third method explained above, a case is explained in which at least a part (for example, the region around the M1 contact CS connecting the gate electrode of the transfer transistor 31 of the right pixel and the first metal layer M1 and under the first metal layer M1 connected to the M1 contact CS) of the interlayer insulating film 67a of the first layer is locally replaced with the insulating film 167 having a dielectric constant lower than that of the interlayer insulating film 67a. However, a region to be replaced with an insulating film having a dielectric constant lower than that of the interlayer insulating film 67a is not limited thereto. For example, as illustrated in FIG. 16, in the interlayer insulating film 67b of the second layer, a region around the first metal layer M1 connected to the gate electrode of the transfer transistor 31 of the right pixel via the M1 contact CS may be locally replaced with an insulating film 167a having a lower dielectric constant than that of the interlayer insulating film 67a and a region around the M2 contact V1 connected to the first metal layer M1 may be locally replaced with an insulating film 167b having a lower dielectric constant than that of the interlayer insulating film 67b.

### 1.11 Summary

As explained above, according to the first embodiment, it is possible to suppress the coupling between the wire of the lookbehind pixel and the floating diffusion region FD and reduce the coupling capacitance by adopting the first method of reducing the wiring area of the lookbehind pixel to reduce the wiring area facing the floating diffusion region FD, the second method of increasing the distance from the wire of the lookbehind pixel to the floating diffusion region FD, the third method of replacing at least a part of the insulating film around the wire of the lookbehind pixel with the insulating film 167 having a low dielectric constant, and the like. Consequently, since it is possible to perform adjustment to suppress a transfer boost amount of the lookbehind pixel, which increases when the transfer transistor 31 is turned on in the same period as a period when the transfer transistor 31 of the lookahead pixel is turned on, it is possible to reduce variations in output signals between the pair of pixels (for example, the right pixel and the left pixel) configuring the image plane phase difference pixel. By making it possible to reduce variations in output signals between the pair of pixels, it is possible to suppress deterioration in image quality. Therefore, for example, it is possible to prevent a time required for focus adjustment from becoming redundant.

According to the present embodiment, it is possible to perform adjustment to suppress the transfer boost amount of the lookbehind pixel. Therefore, it is also possible to achieve effects of, for example, suppressing a decrease in conversion efficiency and alleviating FD white point deterioration at the time of inter-pixel reading.

Further, according to the present embodiment, even when the photoelectric conversion sections PD of the lookahead pixel and the lookbehind pixel are simultaneously reset (PD reset), it is possible to suppress an increase in a transfer boost amount at the time of PD reset. Therefore, it is also possible to suppress FD white spot deterioration due to the PD reset.

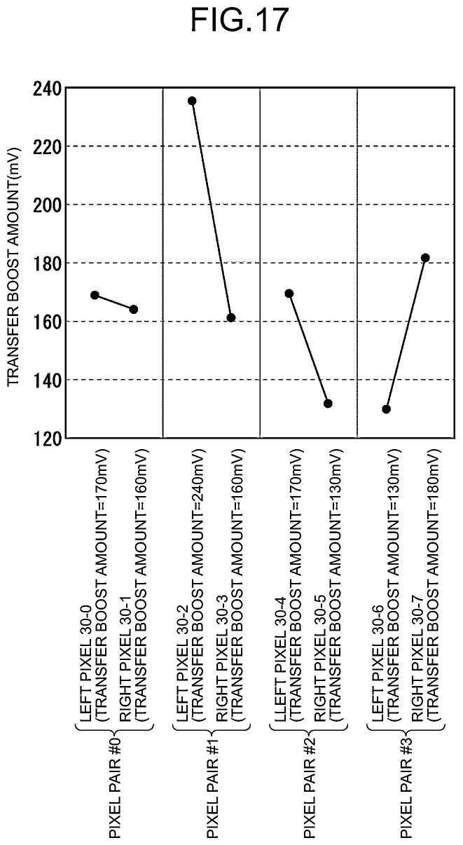

FIG. 17 is a diagram for explaining an effect in the case in which the first method according to the present embodiment is applied to a part of the right pixels and a part of the left pixels. Note that FIG. 17 illustrates a case in which the first method is applied to the right pixel 30-5 of a pixel pair #2 and the left pixel 30-6 of a pixel pair #3 among four pixel pairs #0 to #3, whereby a transfer boost amount of the right pixel 30-5 is reduced from 215 mV (millivolt) to 100 mV and a transfer boost amount of the left pixel 30-6 is reduced from 140 mV to 100 mV.

As illustrated in the pixel pair #2 in FIG. 17, by applying the first method, the transfer boost amount of the right pixel 30-5 can be adjusted to be lower than a transfer boost amount of the left pixel 30-4. Consequently, a transfer boost amount at the time when the right pixel 30-5, which is a lookbehind pixel, is read is avoided excessively increasing because the left pixel 30-4 is simultaneously turned on. Therefore, it is possible to reduce variations in output signals between the left and right pixels and it is also possible to achieve effects of, for example, suppressing a decrease in conversion efficiency and alleviating FD white point deterioration at the time of inter-pixel reading.

### 2. Second Embodiment

Next, a second embodiment of the present disclosure is explained in detail with reference to the drawings. Note that, in the following explanation, about the same components, operations, manufacturing methods, and effects as those in the embodiment explained above, redundant explanation is omitted by citing the components, operations, manufacturing methods, and effects.

A solid-state imaging device and electronic equipment according to the present embodiment may be the same as those according to the first embodiment. However, in the present embodiment, the configuration example of the image plane phase difference pixel is replaced with a configuration example exemplified below.

### 2.1 Planar Layout Example of an Image Plane Phase Difference Pixel

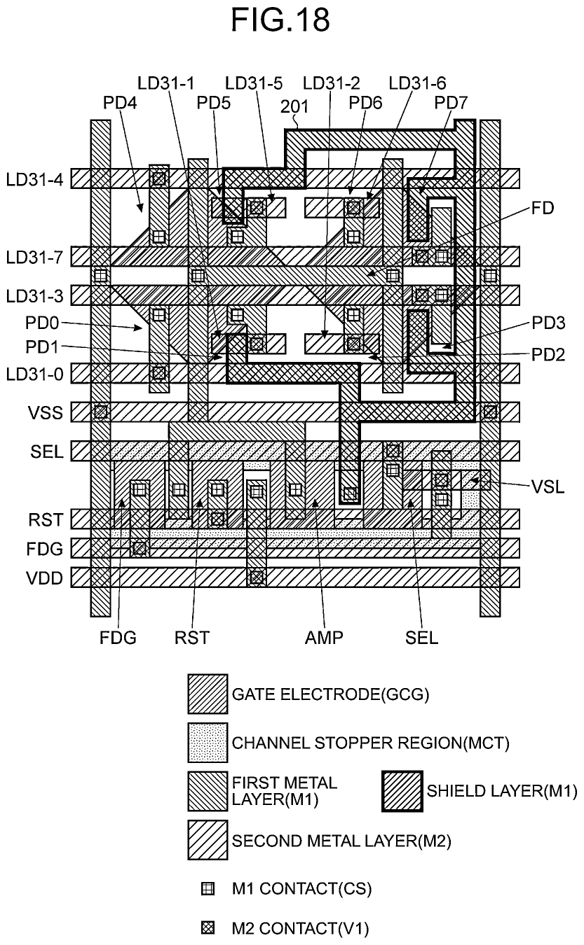

FIG. 18 is a schematic plan view illustrating a planar layout example of the image plane phase difference pixel according to the present embodiment. Note that, in the present embodiment, like the configuration explained with reference to FIG. 7 and the like in the first embodiment, a case including the eight-pixel shared structure in which the eight pixels 30 share one floating diffusion region FD is illustrated. However, the present embodiment is not limited to the eight-pixel shared structure and may have a structure in which two or more pixels 30 share one floating diffusion region FD or may have a structure in which the pixels 30 include individual FDs (that is, do not have the FD shared structure). FIG. 18 illustrates a case in which a pixel circuit including the reset transistor 32, the switching transistor 35, the amplification transistor 33, and the selection transistor 34 (and the floating diffusion region FD) is provided on the semiconductor substrate 58 provided with the eight photoelectric conversion sections PD0 to PD7 and the eight transfer transistors 31. However, not only this, but, for example, as explained with reference to FIG. 5 and the like, the pixel circuit may be provided on the circuit chip 42 side bonded to the semiconductor substrate 58 (the light receiving chip 41).

As illustrated in FIG. 18, in the present embodiment, in a planar structure that is the same as the planar layout example of the image plane phase difference pixel explained with reference to FIG. 7 and the like in the first embodiment, a shield layer 201 for reducing coupling capacitance by suppressing coupling between at least a part of the floating diffusion region FD and at least a part of the transfer transistor drive line LD31 (for example, the transfer transistor drive line LD31 in the first metal layer M1 and/or the second metal layer M2) connected to the transfer transistor 31R of the right pixel 30R is provided in the parts.

In the example illustrated in FIG. 18, the shield layer 201 is provided as a part of the first metal layer M1. In that case, the shield layer 201 may be formed in the same process using the same material as the first metal layer M1. However, not only this, but the shield layer 201 may be provided as a part of the second metal layer M2 or may be provided in a layer (for example, the inside of the interlayer insulating film 67a and/or the interlayer insulating film 67b) different from the first metal layer M1 and the second metal layer M2.

### 2.2 Configuration Example of a Pixel

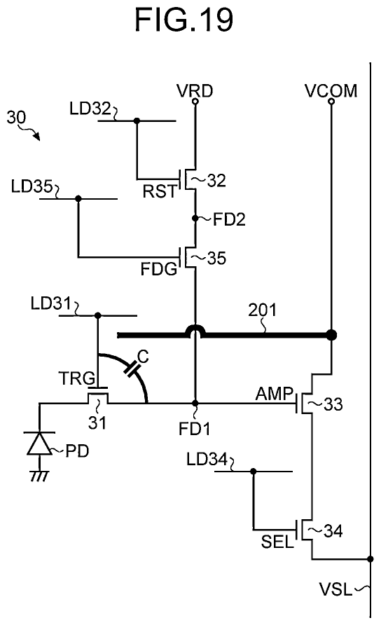

FIG. 19 is a circuit diagram illustrating a schematic configuration example of a pixel according to the present embodiment. Note that FIG. 19 illustrates a circuit diagram in the case in which the pixel does not have an FD shared structure. However, the circuit diagram can also be applied to a case in which the pixel has FD shared structure.

As illustrated in FIG. 19, the shield layer 201 added in the present embodiment may be connected to the source of the amplification transistor 33 configuring a source follower circuit in a pixel circuit. When the shield layer 201 is connected to the source of the amplification transistor 33, the potential of the shield layer 201 can be set to the source potential of the amplification transistor 33. Therefore, for example, it is possible to suppress a decrease in conversion efficiency due to an increase in parasitic capacitance between the floating diffusion region FD and the semiconductor substrate 58 (for example, a GND line). However, not only this, but various modifications such as connection of the shield layer 201 to the GND line may be made.

### 2.3 Summary

As explained above, according to the second embodiment, the shield layer 201 is provided at least a part between at least a part of the floating diffusion region FD and the transfer transistor drive line LD31 connected to the transfer transistor 31R of the right pixel 30R. Consequently, as in the methods according to the first embodiment, it is possible to perform adjustment to suppress a transfer boost amount of the lookbehind pixel that increases when the transfer transistor 31 is turned on in the same period as a period when the transfer transistor 31 of the lookahead pixel is turned on. Therefore, it is possible to reduce variations in output signals between the pair of pixels (for example, the right pixel and the left pixel) configuring the image plane phase difference pixel. By making it possible to reduce variations in output signals between the pair of pixels, it is possible to suppress deterioration in image quality. Therefore, for example, it is possible to prevent a time required for focus adjustment from becoming redundant.

According to the present embodiment, as in the methods according to the first embodiment, it is possible to perform adjustment to suppress the transfer boost amount of the lookbehind pixel. Therefore, it is also possible to achieve effects of, for example, suppressing a decrease in conversion efficiency and alleviating FD white point deterioration at the time of inter-pixel reading.

Further, according to the present embodiment, as in the methods according to the first embodiment, even when the photoelectric conversion sections PD of the lookahead pixel and the lookbehind pixel are simultaneously reset (PD reset), it is possible to suppress an increase in a transfer boost amount at the time of the PD reset. Therefore, it is also possible to suppress FD white spot deterioration due to the PD reset.

Other components, operations, manufacturing methods, and effects may be similar to those in the embodiment explained above. Therefore, detailed explanation thereof is omitted here. The configuration according to the present embodiment can be implemented in combination with other embodiments as appropriate.

### 3. Third Embodiment

Next, a third embodiment of the present disclosure is explained in detail with reference to the drawings. Note that, in the following explanation, about the same components, operations, manufacturing methods, and effects as those in the embodiment explained above, redundant explanation is omitted by citing the components, operations, manufacturing methods, and effects.

In the embodiment explained above, a case illustrated in which coupling between the transfer transistor drive line LD31 of the lookbehind pixel and the floating diffusion region FD is suppressed by structural ingenuity to suppress an increase in the transfer boost amount. In contrast, in the present embodiment, a case in which coupling between the transfer transistor drive line LD31 of the lookbehind pixel and the floating diffusion region FD is suppressed and an increase in the transfer boost amount is suppressed by adjusting drive timing of the transfer transistor 31 is explained as an example.

### 3.1 Operation Example of an Image Plane Phase Difference Pixel

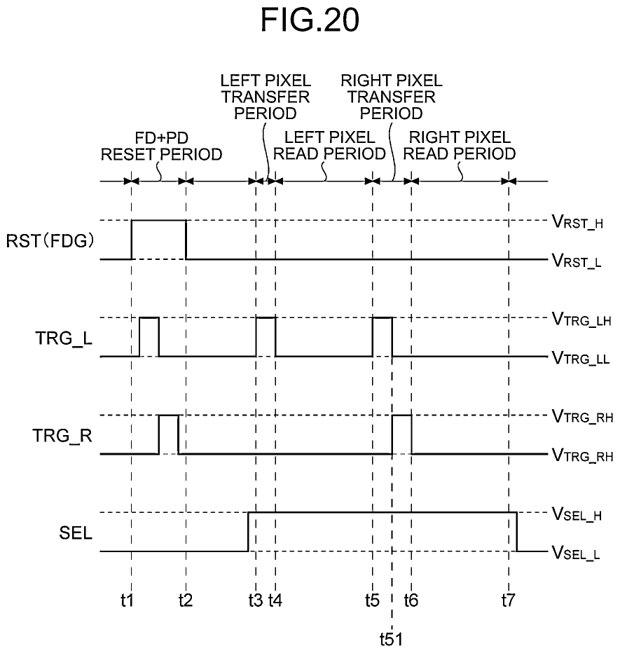

FIG. 20 is a timing chart illustrating an operation example of an image plane phase difference image according to the present embodiment. As illustrated in FIG. 20, in the present embodiment, in a right pixel transfer period at timings t5 to t6, the transfer transistor 31L of the left pixel 30L and the transfer transistor 31R of the right pixel 30R are turned on in different periods. For example, the transfer transistor 31L of the left pixel 30L is turned on at timings t5 to t51 and the transfer transistor 31R of the right pixel 30R is switched to the on state at timing t51 when the transfer transistor 31L of the left pixel 30L is switched from the on state to the off state or thereafter (timings t51 to t6).

As explained above, in the read of the lookbehind pixel, by shifting a period in which the transfer transistor 31 of the lookahead pixel and the transfer transistor 31 of the lookbehind pixel are turned on, the number of transfer transistors 31 that are simultaneously turned on can be reduced. Therefore, it is possible to suppress a significant increase in a transfer boost amount from the transfer transistor 31 of the lookbehind pixel to the floating diffusion region FD.

As illustrated in FIG. 20, also in the FD+PD reset period of timings t1 to t2, the transfer transistor 31L of the left pixel 30L, which is the lookahead pixel, and the transfer transistor 31R of the right pixel 30R, which is the lookbehind pixel, may be turned on in different periods. Consequently, it is possible to suppress an increase in a transfer boost amount at the time of PD reset. Therefore, it is also possible to suppress FD white spot deterioration due to the PD reset.

### 3.2 Summary

As explained above, according to the third embodiment, in the read of the lookbehind pixel, periods in which the transfer transistor 31 of the lookahead pixel and the transfer transistor 31 of the lookbehind pixel are turned on are set to different periods. Consequently, it is possible to reduce the number of transfer transistors 31 that are simultaneously turned on at the time of reading the lookbehind pixel. Therefore, it is possible to reduce variations in output signals between the pair of pixels (for example, the right pixel and the left pixel) configuring the image plane phase difference pixel. By making it possible to reduce variations in output signals between the pair of pixels, it is possible to suppress deterioration in image quality. Therefore, for example, it is possible to prevent a time required for focus adjustment from becoming redundant.

According to the present embodiment, as in the embodiments explained above, it is possible to perform adjustment to suppress a transfer boost amount of the lookbehind pixel. Therefore, it is also possible to achieve effects of, for example, suppressing a decrease in conversion efficiency and alleviating FD white point deterioration at the time of inter-pixel reading.

Further, according to the present embodiment, as in the embodiments explained above, even when the photoelectric conversion sections PD of the lookahead pixel and the lookbehind pixel are simultaneously reset (PD reset), it is possible to suppress an increase in a transfer boost amount at the time of the PD reset. Therefore, it is also possible to suppress FD white spot deterioration due to the PD reset.

Other components, operations, manufacturing methods, and effects may be similar to those in the embodiment explained above. Therefore, detailed explanation thereof is omitted here. The configuration according to the present embodiment can be implemented in combination with other embodiments as appropriate.

### 4. Fourth Embodiment

Next, a fourth embodiment of the present disclosure is explained in detail with reference to the drawings. Note that, in the following explanation, about the same components, operations, manufacturing methods, and effects as those in the embodiment explained above, redundant explanation is omitted by citing the components, operations, manufacturing methods, and effects.

In the third embodiment, at the time of reading the lookbehind pixel, the transfer boost amount at the time of reading the lookbehind pixel is adjusted by shifting an ON period of the transfer transistor 31 of the lookahead pixel and an ON period of the transfer transistor of the lookbehind pixel to reduce the number of transfer transistors 31 that are simultaneously turned on. In contrast, in the present embodiment, variations in output signals between the pair of pixels configuring the image plane phase difference pixel is reduced by adjusting the voltage amplitude of the transfer control signal TRG for turning on the transfer transistor 31 at the time of reading.

### 4.1 Operation Example of an Image Plane Phase Difference Pixel

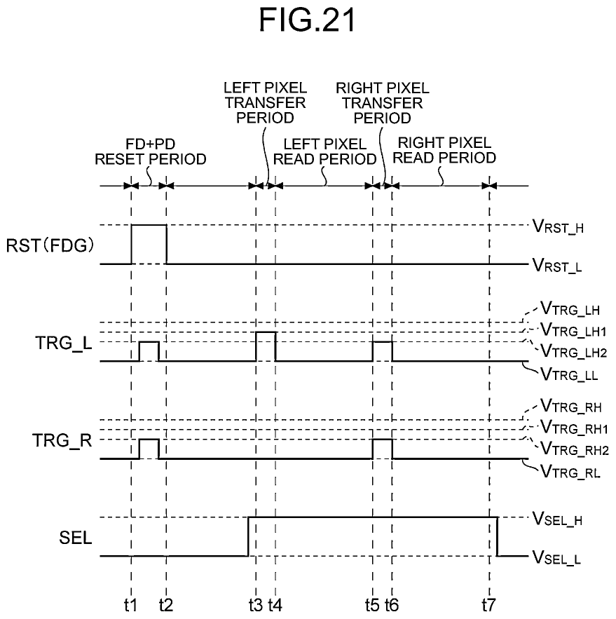

FIG. 21 is a timing chart illustrating an operation example of the image plane phase difference image according to the present embodiment. As illustrated in FIG. 21, in the present embodiment, a plurality of voltage levels are set as the voltage amplitude of the transfer control signal TRG applied to the gate of the transfer transistor 31. In the example illustrated in FIG. 21, three-stage voltage levels V_{TRG_LH}, V_{TRG_LH1}, and V_{TRG_LH2} are set as voltage levels of the transfer control signal TRG applied to the gate of the transfer transistor 31L of the left pixel 30L and three-stage voltage levels V_{TRG_RH}, V_{TRG_RH1}, and V_{TRG_RH2} are also set as voltage levels of the transfer control signal TRG applied to the gate of the transfer transistor 31R of the right pixel 30R. The voltage levels V_{TRG_LL} and V_{TRG_RL} indicate voltage levels in the case in which the transfer control signal TRG is at a low level.

In such a configuration, in in read for the left pixel 30L, which is the lookahead pixel, for example, during a left pixel transfer period, the transfer control signal TRG_L at the voltage level V_{TRG_LH1} is applied to the gate of the transfer transistor 31L of the left pixel 30L.

On the other hand, in read of the right pixel 30R, which is the lookbehind pixel, for example, during a right pixel transfer period, the transfer control signal TRG_L at the voltage level V_{TRG_LH2} lower than the voltage level V_{TRG_LH1} is applied to the gate of the transfer transistor 31L of the left pixel 30L and the gate of the transfer transistor 31R of the right pixel 30R. That is, when the transfer transistor 31 of the lookahead pixel and the transfer transistor 31 of the lookbehind pixel are simultaneously turned on (see timings t5 to t6), the transfer control signal TRG having a voltage level lower than a voltage level of the transfer control signal TRG applied to the gate of the transfer transistor 31 is applied to the gate of the transfer transistor 31 of the lookahead pixel and the gate of the transfer transistor 31 of the lookbehind pixel when only the transfer transistor 31 of the lookahead pixel is turned on (see timings t3 to t4), Further, in other words, in the present embodiment, the voltage level of the transfer control signal TRG applied to the gates of the transfer transistors 31 is lower as the number of the transfer transistors 31 simultaneously turned on is larger.

As explained above, by lowering the voltage level of the transfer control signal TRG at the time of read for the lookbehind pixel in which the number of the transfer transistors 31 to be simultaneously turned on is large, it is possible to reduce an increase amount of a transfer boost amount due to individual voltage application. Therefore, it is possible to suppress an increase in a transfer boost amount from the transfer transistor 31 of the lookbehind pixel to the floating diffusion region FD.

As illustrated in FIG. 20, also in a FD+PD reset period at timings t1 to t2, by setting a voltage level of the transfer control signal TRG applied to the gate of the transfer transistor 31 of the prefetched pixel and the gate of the transfer transistor 31 of the look-ahead pixel to be lower than, for example, a voltage level of the transfer control signal TRG applied to the gate of the transfer transistor 31 when only the transfer transistor 31 of the look-ahead pixel is turned on (see timings t3 to t4), it is possible to suppress an increase in a transfer boost amount at the time of PD reset. Therefore, it is also possible to suppress FD white spot deterioration due to the PD reset.

Note that the difference between a voltage level of the transfer control signal TRG applied to the gate of the transfer transistor 31 of the lookahead pixel at the time of lookahead and a voltage level of the transfer control signal TRG applied to the gates of the transfer transistors 31 of the lookahead pixel and the lookbehind pixel at the time of lookbehind may be determined on the basis of a difference, a ratio, or the like between the number of added pixels at the time of the lookahead and the number of added pixels at the time of the lookbehind. For example, when the number of added pixels can be switched (for example, when a plurality of stages of binning modes are provided), the voltage level of the transfer control signal TRG may be set to four or more levels according to the number of added pixels. When the number of added pixels is “1” (that is, there is no pixel addition), the transfer control signal TRG at the voltage level V_{TRG_LH} or V_{TRG_RH} may be applied to the gate of the transfer transistor 31 of a read target pixel.

### 4.1.1 Modification of an Operation of the Image Plane Phase Difference Pixel

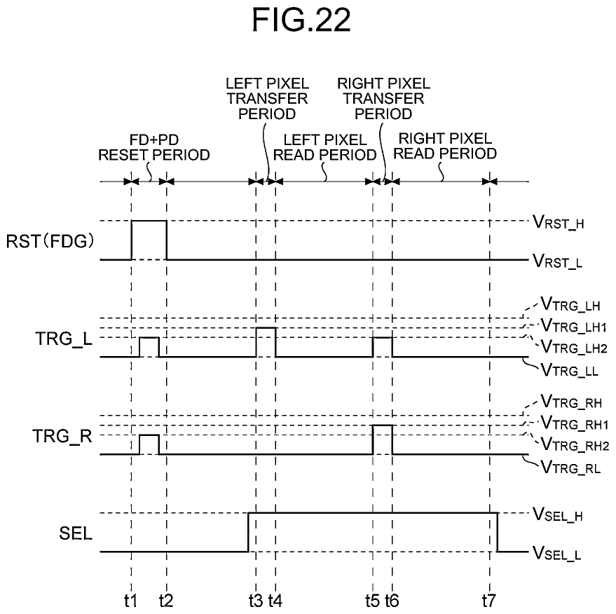

FIG. 22 is a timing chart illustrating an operation example of an image plane phase difference image according to a modification of the present embodiment. In the operation example illustrated in FIG. 22, in the same operation as the operation example illustrated in FIG. 21, a voltage level (V_{TRG_RH1}) of the transfer control signal TRG_R applied to the gate of the transfer transistor 31R of the lookbehind pixel (in this example, the right pixel 30R) to be read at the time of lookbehind is set higher than a voltage level (V_{TRG_LH2}) of the transfer control signal TRG_L applied to the gate of the transfer transistor 31R of the lookahead pixel (in this example, the left pixel 30L) not to be read at the time of lookbehind. In the example illustrated in FIG. 22, the voltage level (V_{TRG_RH1}) of the transfer control signal TRG_R applied to the gate of the transfer transistor 31R of the lookbehind pixel (in this example, the right pixel 30R) to be read at the time of lookbehind is set to a voltage level substantially equal to a voltage level (V_{TRG_LH1}) of the transfer control signal TRG_L applied to the gate of the transfer transistor 31L of the lookahead pixel (in this example, the left pixel 30L) at the time of lookahead.

By setting the voltage level of the transfer control signal TRG applied to the gate of the transfer transistor 31 of the lookbehind pixel to be read at the time of lookbehind higher than the voltage level of the transfer control signal TRG applied to the gate of the transfer transistor 31 of the lookahead pixel not to be read as explained above, it is possible to prevent transfer efficiency of electric charges from the lookbehind pixel at the time of lookbehind from decreasing.

Other operations may be the same as the operation example explained with reference to FIG. 21. Therefore, detailed explanation of the other operations is omitted here.

### 4.2 Summary

As explained above, according to the fourth embodiment, the voltage level of the transfer control signal TRG applied to the gate of the transfer transistor 31 of at least one of the lookahead pixel and the lookbehind pixel at the time of reading the lookbehind pixel is set to the voltage level lower than the voltage level of the transfer control signal TRG applied to the gate of the transfer transistor 31 of the lookahead pixel at the time of lookahead. Consequently, it is possible to suppress an increase in a transfer boost amount at the time of lookbehind. Therefore, it is possible to reduce variations in output signals between the pair of pixels (for example, the right pixel and the left pixel) configuring the image plane phase difference pixel. By making it possible to reduce variations in output signals between the pair of pixels, it is possible to suppress deterioration in image quality. Therefore, for example, it is possible to prevent a time required for focus adjustment from becoming redundant.

According to the present embodiment, as in the embodiments explained above, it is possible to perform adjustment to suppress a transfer boost amount of the lookbehind pixel. Therefore, it is also possible to achieve effects of, for example, suppressing a decrease in conversion efficiency and alleviating FD white point deterioration at the time of inter-pixel reading.

Further, according to the present embodiment, as in the embodiments explained above, even when the photoelectric conversion sections PD of the lookahead pixel and the lookbehind pixel are simultaneously reset (PD reset), it is possible to suppress an increase in a transfer boost amount at the time of the PD reset. Therefore, it is also possible to suppress FD white spot deterioration due to the PD reset.

Other components, operations, manufacturing methods, and effects may be similar to those in the embodiment explained above. Therefore, detailed explanation thereof is omitted here. The configuration according to the present embodiment can be implemented in combination with other embodiments as appropriate.

### 5. Application Example to a Smartphone

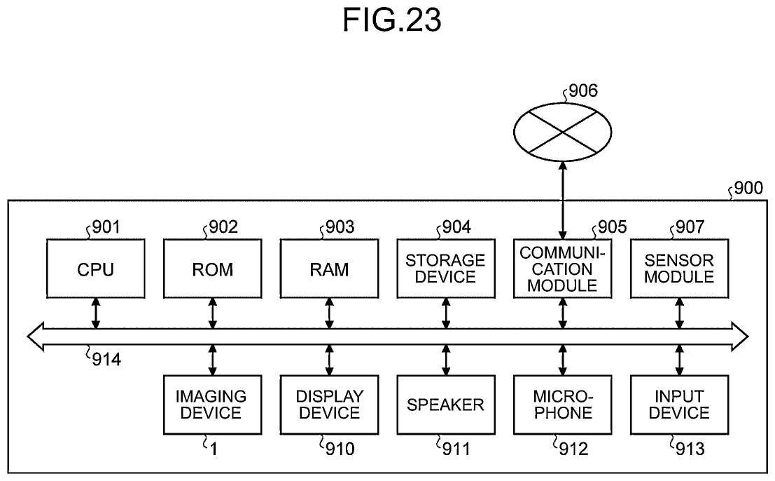

The technology according to the present disclosure (the present technology) can be further applied to various products. For example, the technology according to the present disclosure may be applied to a smartphone or the like. Therefore, a configuration example of a smartphone 900 as electronic equipment to which the present technology is applied is explained with reference to FIG. 23. FIG. 23 is a block diagram illustrating an example of a schematic functional configuration of the smartphone 900 to which the technology according to the present disclosure (the present technology) can be applied.

As illustrated in FIG. 23, the smartphone 900 includes a CPU (Central Processing Unit) 901, a ROM (Read Only Memory) 902, and a RAM (Random Access Memory) 903. The smartphone 900 includes a storage device 904, a communication module 905, and a sensor module 907. Further, the smartphone 900 includes an imaging device 1, a display device 910, a speaker 911, a microphone 912, an input device 913, and a bus 914. The smartphone 900 may include a processing circuit such as a DSP (Digital Signal Processor) instead of or together with the CPU 901.

The CPU 901 functions as an arithmetic processing device and a control device and controls an entire operation or a part of the operation in the smartphone 900 according to various programs recorded in the ROM 902, the RAM 903, the storage device 904, or the like. The ROM 902 stores programs, arithmetic operation parameters, and the like to be used by the CPU 901. The RAM 903 primarily stores programs to be used in execution of the CPU 901, parameters that change as appropriate in the execution, and the like. The CPU 901, the ROM 902, and the RAM 903 are connected to one another by the bus 914. The storage device 904 is a device for data storage configured as an example of a storage unit of the smartphone 900. The storage device 904 includes, for example, a magnetic storage device such as a HDD (Hard Disk Drive), a semiconductor storage device, or an optical storage device. The storage device 904 stores programs to be executed by the CPU 901, various data, various data acquired from the outside, and the like.

The communication module 905 is a communication interface configured by, for example, a communication device for connecting to a communication network 906. The communication module 905 can be, for example, a communication card for a wired or wireless LAN (Local Area Network), Bluetooth (registered trademark), or WUSB (Wireless USB). The communication module 905 may be a router for optical communication, a router for ADSL (Asymmetric Digital Subscriber Line), a modem for various kinds of communication, or the like. The communication module 905 transmits and receives signals and the like to and from, for example, the Internet and other communication equipment using a predetermined protocol such as TCP (Transmission Control Protocol)/IP (Internet Protocol). The communication network 906 connected to the communication module 905 is a network connected by wire or radio and is, for example, the Internet, a home LAN, infrared communication, or satellite communication.

The sensor module 907 includes various sensors such as a motion sensor (for example, an acceleration sensor, a gyro sensor, or a geomagnetic sensor), a biological information sensor (for example, a pulse sensor, a blood pressure sensor, or a fingerprint sensor), or a position sensor (for example, a GNSS (Global Navigation Satellite System) receiver).

The imaging device 1 is provided on the surface of the smartphone 900 and can image a target object or the like located on the rear side or the front side of the smartphone 900. Specifically, the imaging device 1 can include an imaging element (not illustrated) such as a CMOS (Complementary MOS) image sensor to which the technology according to the present disclosure (the present technology) can be applied and a signal processing circuit (not illustrated) that applies imaging signal processing to a signal photoelectrically converted by the imaging element. Further, the imaging device 1 can further include an optical system mechanism (not illustrated) configured by an imaging lens, a zoom lens, a focus lens, and the like and a drive system mechanism (not illustrated) that controls an operation of the optical system mechanism. The imaging element can condense incident light from the target object as an optical image. The signal processing circuit can acquire a captured image by photo-electrically converting the formed optical image in units of pixels, reading signals of the pixels as imaging signals, and performing image processing.

The display device 910 is provided on the surface of the smartphone 900 and can be a display device such as an LCD (Liquid Crystal Display) or an organic EL (Electro Luminescence) display. The display device 910 can display an operation screen, a captured image acquired by the imaging device 1 explained above, and the like.

The speaker 911 can output, for example, call voice, voice incidental to video content displayed by the display device 910 explained above, and the like to a user.

The microphone 912 can collect, for example, call voice of the user, voice including a command to start a function of the smartphone 900, and voice in a surrounding environment of the smartphone 900.

The input device 913 is a device operated by the user such as a button, a keyboard, a touch panel, or a mouse. The input device 913 includes an input control circuit that generates an input signal on the basis of information input by the user and outputs the input signal to the CPU 901. By operating the input device 913, the user can input various data to the smartphone 900 and instruct the smartphone 900 to perform a processing operation.

The configuration example of the smartphone 900 is explained above. The components explained above may be configured using general-purpose members or may include hardware specialized for the functions of the components. Such a configuration can be changed as appropriate according to a technical level at each time when the configuration is implemented.

### 6. Application Example to a Mobile Body

The technology according to the present disclosure (the present technology) can be applied to various products. For example, the technology according to the present disclosure may be implemented as a device mounted on a mobile body of any type such as an automobile, an electric vehicle, a hybrid electric vehicle, a motorcycle, a bicycle, a personal mobility, an airplane, a drone, a ship, and a robot.

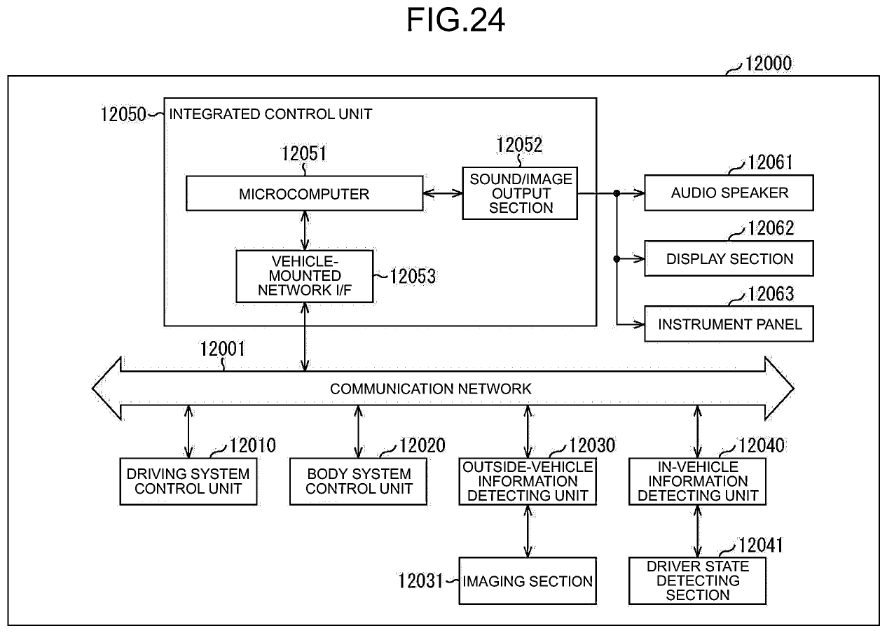

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

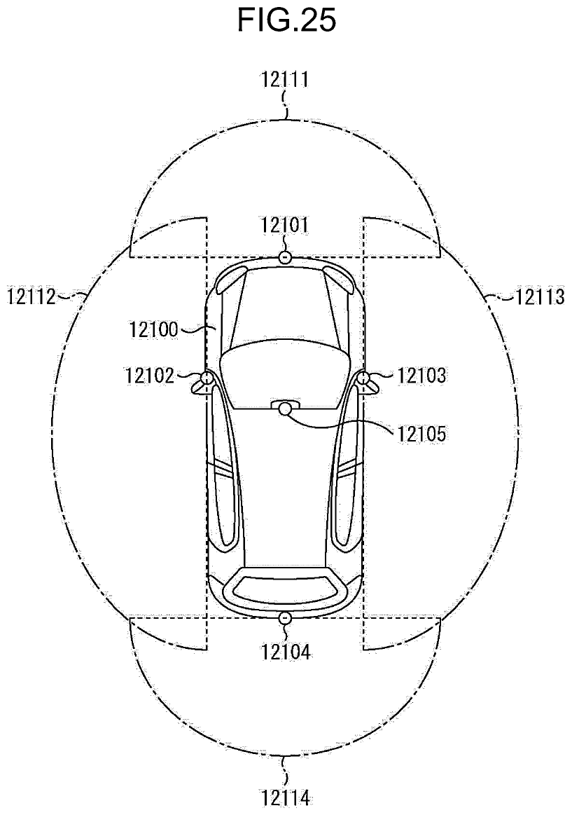

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of a vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied is explained above. The technology according to the present disclosure can be applied to the imaging section 12031 and the like among the components explained above. By applying the technology according to the present disclosure to the imaging section 12031, a clearer captured image can be obtained. Therefore, it is possible to reduce driver's fatigue.

### 7. Application Example to an Endoscopic Surgery System

The technology according to the present disclosure (the present technology) can be applied to various products. For example, the technology according to the present disclosure may be applied to an endoscopic surgery system.

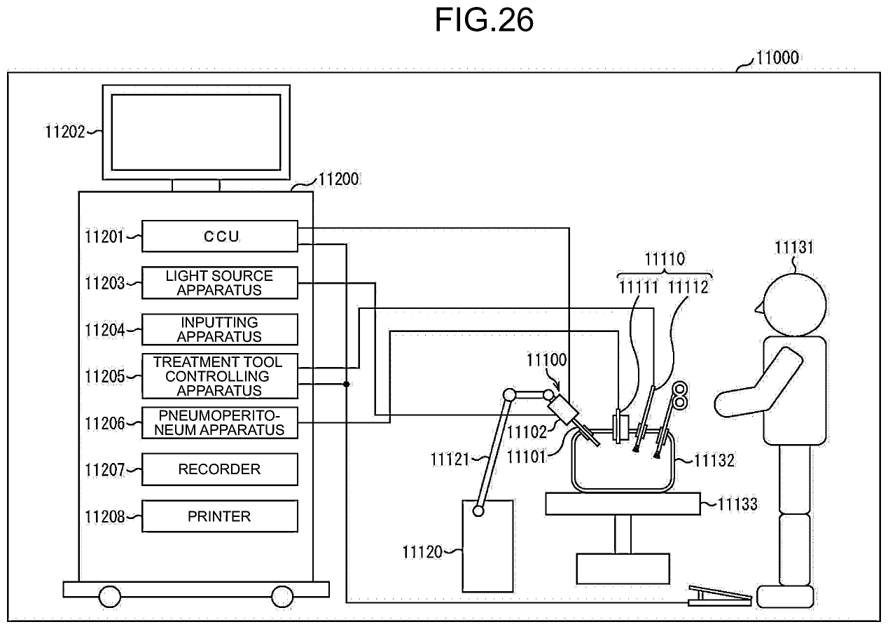

FIG. 26 is a view depicting an example of a schematic configuration of an endoscopic surgery system to which the technology according to an embodiment of the present disclosure (present technology) can be applied.

In FIG. 26, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

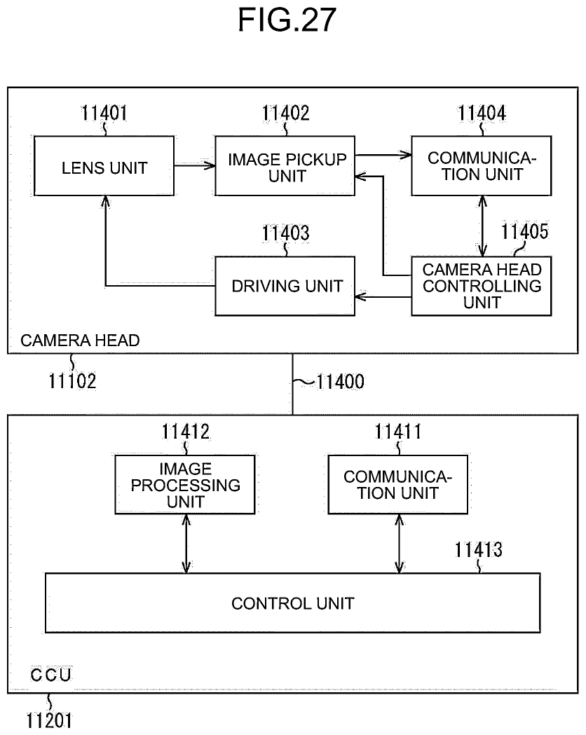

FIG. 27 is a block diagram depicting an example of a functional configuration of the camera head 11102 and the CCU 11201 depicted in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied is explained above. The technology according to the present disclosure can be applied to, for example, the image pickup unit 11402 of the camera head 11102 among the components explained above. By applying the technology according to the present disclosure to the camera head 11102, a clearer image of the surgical region can be obtained. Therefore, the surgeon can reliably confirm the surgical region.

Note that, here, the endoscopic surgery system is explained as an example. However, besides, the technology according to the present disclosure may be applied to, for example, a microscopic surgery system.

Although the embodiments of the present disclosure are explained above, the technical scope of the present disclosure is not limited to the embodiments explained above per se. Various changes are possible without departing from the gist of the present disclosure. Components in different embodiments and modifications may be combined as appropriate.

The effects in the embodiments explained in this specification are only illustrations and are not limited. Other effects may be present.

Note that the present technology can also take the following configurations.
(1) A solid-state imaging device comprising:
   a first photoelectric conversion section that generates an electric charge corresponding to an incident light amount;
   a second photoelectric conversion section that is adjacent to the first photoelectric conversion section and generates an electric charge corresponding to an incident light amount;
   a floating diffusion region that accumulates the electric charge generated in at least one of the first photoelectric conversion section and the second photoelectric conversion section;
   a first transfer transistor connected between the first photoelectric conversion section and the floating diffusion region;
   a second transfer transistor connected between the second photoelectric conversion section and the floating diffusion region;
   a first drive line connected to a gate of the first transfer transistor; and
   a second drive line connected to a gate of the second transfer transistor, wherein
   coupling capacitance between the second drive line and the floating diffusion region is smaller than coupling capacitance between the first drive line and the floating diffusion region.
(2) The solid-state imaging device according to (1), wherein an area of facing of the second drive line and the floating diffusion region is smaller than an area of facing of the first drive line and the floating diffusion region.
(3) The solid-state imaging device according to (2), wherein
   the first photoelectric conversion section and the second photoelectric conversion section are provided in adjacent pixel regions in a semiconductor substrate,
   the first transfer transistor and the second transfer transistor are provided on an element forming surface of the semiconductor substrate,
   the first drive line includes a first metal wire provided on a first interlayer insulating film located on the element forming surface of the semiconductor substrate and a first contact wire connecting the first metal wire and the gate of the first transfer transistor,
   the second drive line includes a second metal wire provided on the first interlayer insulating film and a second contact wire connecting the second metal wire and the gate of the second transfer transistor,
   the floating diffusion region includes a third metal wire provided on the first interlayer insulating film,
   the area of the facing of the first drive line and the floating diffusion region is an area of facing of the first metal wire and the third metal wire, and
   the area of the facing of the second drive line and the floating diffusion region is an area of facing of the second metal wire and the third metal wire.
(4) The solid-state imaging device according to any one of (1) to (3), wherein
   a distance from the second drive line to the floating diffusion region is longer than a distance from the first drive line to the floating diffusion region.
(5) The solid-state imaging device according to (4), wherein the first photoelectric conversion section and the second photoelectric conversion section are provided in adjacent pixel regions in the semiconductor substrate,
   the first transfer transistor and the second transfer transistor are provided on an element forming surface of the semiconductor substrate,
   the first drive line includes a first metal wire provided on a first interlayer insulating film located on the element forming surface of the semiconductor substrate and a first contact wire connecting the first metal wire and the gate of the first transfer transistor,
   the second drive line includes a second metal wire provided on the first interlayer insulating film and a second contact wire connecting the second metal wire and the gate of the second transfer transistor,
   the floating diffusion region includes a third metal wire provided on the first interlayer insulating film,
   a distance from the first drive line to the floating diffusion region is a shortest distance or an average distance from the first metal wire to the third metal wire, and
   a distance from the second drive line to the floating diffusion region is a shortest distance or an average distance from the second metal wire to the third metal wire.
(6) The solid-state imaging device according to any one of (1) to (5), wherein
   a dielectric constant of an insulating layer located around at least a part of the second drive line is lower than a dielectric constant of an insulating layer located around the first drive line.
(7) The solid-state imaging device according to (6), wherein
   the first photoelectric conversion section and the second photoelectric conversion section are provided in adjacent pixel regions in a semiconductor substrate,
   the first transfer transistor and the second transfer transistor are provided on an element forming surface of the semiconductor substrate,
   the first drive line includes a first metal wire provided on a first interlayer insulating film located on the element forming surface of the semiconductor substrate and a first contact wire connecting the first metal wire and the gate of the first transfer transistor,
   the second drive line includes a second metal wire provided on the first interlayer insulating film and a second contact wire connecting the second metal wire and the gate of the second transfer transistor,
   the floating diffusion region includes a third metal wire provided on the first interlayer insulating film, and
   a periphery of at least a part of the second contact wire is covered with a first insulating film having a dielectric constant lower than that of the first interlayer insulating film.
(8) The solid-state imaging device according to (7), wherein
   the first drive line further includes a fourth metal wire provided on a second interlayer insulating film located on the first interlayer insulating film and a third contact wire connecting the fourth metal wire and the first metal wire,
   the second drive line further includes a fifth metal wire provided on a second interlayer insulating film located on the first interlayer insulating film and a fourth contact wire connecting the fifth metal wire and the second metal wire, and
   a periphery of at least a part of the fourth contact wire is covered with a second insulating film having a dielectric constant lower than that of the second interlayer insulating film.
(9) The solid-state imaging device according to any one of (1) to (8), further comprising
   a shield layer disposed in at least a part between the second drive line and the floating diffusion region.
(10) The solid-state imaging device according to (9), wherein
   the first photoelectric conversion section and the second photoelectric conversion section are provided in adjacent pixel regions of a semiconductor substrate,
   the first transfer transistor and the second transfer transistor are provided on an element forming surface of the semiconductor substrate,
   the first drive line includes a first metal wire provided on a first interlayer insulating film located on the element forming surface of the semiconductor substrate and a first contact wire connecting the first metal wire and the gate of the first transfer transistor,
   the second drive line includes a second metal wire provided on the first interlayer insulating film and a second contact wire connecting the second metal wire and the gate of the second transfer transistor,
   the floating diffusion region includes a third metal wire provided on the first interlayer insulating film, and
   the shield layer is disposed between the second metal wire and the third metal wire on the first interlayer insulating film.
(11) The solid-state imaging device according to (9) or (10), further comprising
   an amplification transistor having a gate connected to the floating diffusion region, wherein
   the shield layer is connected to a source of the amplification transistor.
(12) A solid-state imaging device comprising:
   a first photoelectric conversion section that generates an electric charge corresponding to an incident light amount;
   a second photoelectric conversion section that is adjacent to the first photoelectric conversion section and generates an electric charge corresponding to an incident light amount;
   a floating diffusion region that accumulates the electric charge generated in at least one of the first photoelectric conversion section and the second photoelectric conversion section;
   a first transfer transistor connected between the first photoelectric conversion section and the floating diffusion region;
   a second transfer transistor connected between the second photoelectric conversion section and the floating diffusion region;
   a first drive line connected to a gate of the first transfer transistor;
   a second drive line connected to a gate of the second transfer transistor; and
   a drive circuit that applies a drive signal to each of the first drive line and the second drive line, wherein
   the first photoelectric conversion section, the first transfer transistor, and the floating diffusion region configure a first pixel,
   the second photoelectric conversion section, the second transfer transistor, and the floating diffusion region configure a second pixel, and
   the drive circuit applies a first drive signal to the first drive line at a time of read from the first pixel and applies a third drive signal to the second drive line after applying a second drive signal to the first drive line at a time of read from the second pixel.
(13) A solid-state imaging device comprising:
   a first photoelectric conversion section that generates an electric charge corresponding to an incident light amount;
   a second photoelectric conversion section that is adjacent to the first photoelectric conversion section and generates an electric charge corresponding to an incident light amount;
   a floating diffusion region that accumulates the electric charge generated in at least one of the first photoelectric conversion section and the second photoelectric conversion section;
   a first transfer transistor connected between the first photoelectric conversion section and the floating diffusion region;
   a second transfer transistor connected between the second photoelectric conversion section and the floating diffusion region;
   a first drive line connected to a gate of the first transfer transistor;
   a second drive line connected to a gate of the second transfer transistor; and
   a drive circuit that applies a drive signal to each of the first drive line and the second drive line, wherein
   the first photoelectric conversion section, the first transfer transistor, and the floating diffusion region configure a first pixel,
   the second photoelectric conversion section, the second transfer transistor, and the floating diffusion region configure a second pixel,
   the drive circuit applies a first drive signal to the first drive line at a time of read from the first pixel and applies a second drive signal to the first drive line and applies a third drive signal to the second drive line at a time of read from the second pixel, and
   a voltage level of at least one of the second drive signal and the third drive signal is lower than a voltage level of the first drive signal.
(14) The solid-state imaging device according to (13), wherein
   a voltage level of the second drive signal is lower than a voltage level of the first drive signal, and
   a voltage level of the third drive signal is equal to a voltage level of the first drive signal.
(15) The solid-state imaging device according to (13), wherein
   a voltage level of the second drive signal is lower than a voltage level of the first drive signal, and
   a voltage level of the third drive signal is higher than a voltage level of the second drive signal.
(16) Electronic equipment comprising:
   the solid-state imaging device according to any one of (1) to (15); and
   a processor that executes predetermined processing on image data output from the solid-state imaging device.

### REFERENCE SIGNS LIST

1 ELECTRONIC EQUIPMENT (IMAGING DEVICE)
10 SOLID-STATE IMAGING DEVICE
11 IMAGING LENS
13 PROCESSOR
14 STORAGE UNIT
21 PIXEL ARRAY UNIT
22 VERTICAL DRIVE CIRCUIT
23 COLUMN PROCESSING UNIT
24 HORIZONTAL DRIVE CIRCUIT
25 SYSTEM CONTROL UNIT
26 SIGNAL PROCESSING UNIT
27 DATA STORAGE UNIT
30, 30A PIXEL
30L, 30-0, 30-2, 30-4, 30-6 LEFT PIXEL
30R, 30-1, 30-3, 30-5, 30-7 RIGHT PIXEL
31, 31L, 31R TRANSFER TRANSISTOR
32 RESET TRANSISTOR
33 AMPLIFICATION TRANSISTOR
34 SELECTION TRANSISTOR
35 SWITCHING TRANSISTOR
41 LIGHT RECEIVING CHIP
42 CIRCUIT CHIP
51 ON-CHIP LENS
52 COLOR FILTER
53 PLANARIZATION FILM
54 LIGHT BLOCKING FILM
55, 63, 67d, 167, 167a, 167b INSULATING FILM
56, 64 P-TYPE SEMICONDUCTOR REGION
57 LIGHT RECEIVING SURFACE
58 SEMICONDUCTOR SUBSTRATE
59 N-TYPE SEMICONDUCTOR REGION
60 PIXEL SEPARATION SECTION
61 GROOVE
62 FIXED CHARGE FILM
65, 65A to 65C WIRING LAYER
66 WIRE
67 INSULATING LAYER
67a to 67c INTERLAYER INSULATING FILM
201 SHIELD LAYER
CS M1 CONTACT
FD FLOATING DIFFUSION REGION
FD1 FIRST FLOATING DIFFUSION REGION
FD2 SECOND FLOATING DIFFUSION REGION
LD PIXEL DRIVE LINE
LD31, LD31-0 to LD31-7 TRANSFER TRANSISTOR DRIVE LINE
LD32 RESET TRANSISTOR DRIVE LINE
LD34 SELECTION TRANSISTOR DRIVE LINE
LD35 SWITCHING TRANSISTOR DRIVE LINE
M1 FIRST METAL LAYER
M2 SECOND METAL LAYER
PD, PD0 to PD7, PD_L, PD_R PHOTOELECTRIC CONVERSION SECTION
V1 M2 CONTACT
VSL VERTICAL SIGNAL LINE

1. A solid-state imaging device comprising:
a first photoelectric conversion section that generates an electric charge corresponding to an incident light amount;
a second photoelectric conversion section that is adjacent to the first photoelectric conversion section and generates an electric charge corresponding to an incident light amount;
a floating diffusion region that accumulates the electric charge generated in at least one of the first photoelectric conversion section and the second photoelectric conversion section;
a first transfer transistor connected between the first photoelectric conversion section and the floating diffusion region;
a second transfer transistor connected between the second photoelectric conversion section and the floating diffusion region;
a first drive line connected to a gate of the first transfer transistor; and
a second drive line connected to a gate of the second transfer transistor, wherein
coupling capacitance between the second drive line and the floating diffusion region is smaller than coupling capacitance between the first drive line and the floating diffusion region.

2. The solid-state imaging device according to claim 1, wherein an area of facing of the second drive line and the floating diffusion region is smaller than an area of facing of the first drive line and the floating diffusion region.

3. The solid-state imaging device according to claim 2, wherein
the first photoelectric conversion section and the second photoelectric conversion section are provided in adjacent pixel regions in a semiconductor substrate,
the first transfer transistor and the second transfer transistor are provided on an element forming surface of the semiconductor substrate,
the first drive line includes a first metal wire provided on a first interlayer insulating film located on the element forming surface of the semiconductor substrate and a first contact wire connecting the first metal wire and the gate of the first transfer transistor,
the second drive line includes a second metal wire provided on the first interlayer insulating film and a second contact wire connecting the second metal wire and the gate of the second transfer transistor,
the floating diffusion region includes a third metal wire provided on the first interlayer insulating film,
the area of the facing of the first drive line and the floating diffusion region is an area of facing of the first metal wire and the third metal wire, and
the area of the facing of the second drive line and the floating diffusion region is an area of facing of the second metal wire and the third metal wire.

4. The solid-state imaging device according to claim 1, wherein
a distance from the second drive line to the floating diffusion region is longer than a distance from the first drive line to the floating diffusion region.

5. The solid-state imaging device according to claim 4, wherein
the first photoelectric conversion section and the second photoelectric conversion section are provided in adjacent pixel regions in the semiconductor substrate,
the first transfer transistor and the second transfer transistor are provided on an element forming surface of the semiconductor substrate,
the first drive line includes a first metal wire provided on a first interlayer insulating film located on the element forming surface of the semiconductor substrate and a first contact wire connecting the first metal wire and the gate of the first transfer transistor,
the second drive line includes a second metal wire provided on the first interlayer insulating film and a second contact wire connecting the second metal wire and the gate of the second transfer transistor,
the floating diffusion region includes a third metal wire provided on the first interlayer insulating film,
a distance from the first drive line to the floating diffusion region is a shortest distance or an average distance from the first metal wire to the third metal wire, and
a distance from the second drive line to the floating diffusion region is a shortest distance or an average distance from the second metal wire to the third metal wire.

6. The solid-state imaging device according to claim 1, wherein
a dielectric constant of an insulating layer located around at least a part of the second drive line is lower than a dielectric constant of an insulating layer located around the first drive line.

7. The solid-state imaging device according to claim 6, wherein
the first photoelectric conversion section and the second photoelectric conversion section are provided in adjacent pixel regions in a semiconductor substrate,
the first transfer transistor and the second transfer transistor are provided on an element forming surface of the semiconductor substrate,
the first drive line includes a first metal wire provided on a first interlayer insulating film located on the element forming surface of the semiconductor substrate and a first contact wire connecting the first metal wire and the gate of the first transfer transistor,
the second drive line includes a second metal wire provided on the first interlayer insulating film and a second contact wire connecting the second metal wire and the gate of the second transfer transistor,
the floating diffusion region includes a third metal wire provided on the first interlayer insulating film, and
a periphery of at least a part of the second contact wire is covered with a first insulating film having a dielectric constant lower than that of the first interlayer insulating film.

8. The solid-state imaging device according to claim 7, wherein
the first drive line further includes a fourth metal wire provided on a second interlayer insulating film located on the first interlayer insulating film and a third contact wire connecting the fourth metal wire and the first metal wire,
the second drive line further includes a fifth metal wire provided on a second interlayer insulating film located on the first interlayer insulating film and a fourth contact wire connecting the fifth metal wire and the second metal wire, and
a periphery of at least a part of the fourth contact wire is covered with a second insulating film having a dielectric constant lower than that of the second interlayer insulating film.

9. The solid-state imaging device according to claim 1, further comprising
a shield layer disposed in at least a part between the second drive line and the floating diffusion region.

10. The solid-state imaging device according to claim 9, wherein
the first photoelectric conversion section and the second photoelectric conversion section are provided in adjacent pixel regions of a semiconductor substrate,
the first transfer transistor and the second transfer transistor are provided on an element forming surface of the semiconductor substrate,
the first drive line includes a first metal wire provided on a first interlayer insulating film located on the element forming surface of the semiconductor substrate and a first contact wire connecting the first metal wire and the gate of the first transfer transistor,
the second drive line includes a second metal wire provided on the first interlayer insulating film and a second contact wire connecting the second metal wire and the gate of the second transfer transistor,
the floating diffusion region includes a third metal wire provided on the first interlayer insulating film, and
the shield layer is disposed between the second metal wire and the third metal wire on the first interlayer insulating film.

11. The solid-state imaging device according to claim 9, further comprising
an amplification transistor having a gate connected to the floating diffusion region, wherein
the shield layer is connected to a source of the amplification transistor.

12. A solid-state imaging device comprising:
a first photoelectric conversion section that generates an electric charge corresponding to an incident light amount;
a second photoelectric conversion section that is adjacent to the first photoelectric conversion section and generates an electric charge corresponding to an incident light amount;
a floating diffusion region that accumulates the electric charge generated in at least one of the first photoelectric conversion section and the second photoelectric conversion section;
a first transfer transistor connected between the first photoelectric conversion section and the floating diffusion region;
a second transfer transistor connected between the second photoelectric conversion section and the floating diffusion region;
a first drive line connected to a gate of the first transfer transistor;
a second drive line connected to a gate of the second transfer transistor; and
a drive circuit that applies a drive signal to each of the first drive line and the second drive line, wherein
the first photoelectric conversion section, the first transfer transistor, and the floating diffusion region configure a first pixel,
the second photoelectric conversion section, the second transfer transistor, and the floating diffusion region configure a second pixel, and
the drive circuit applies a first drive signal to the first drive line at a time of read from the first pixel and applies a third drive signal to the second drive line after applying a second drive signal to the first drive line at a time of read from the second pixel.

13. A solid-state imaging device comprising:
a first photoelectric conversion section that generates an electric charge corresponding to an incident light amount;
a second photoelectric conversion section that is adjacent to the first photoelectric conversion section and generates an electric charge corresponding to an incident light amount;
a floating diffusion region that accumulates the electric charge generated in at least one of the first photoelectric conversion section and the second photoelectric conversion section;
a first transfer transistor connected between the first photoelectric conversion section and the floating diffusion region;
a second transfer transistor connected between the second photoelectric conversion section and the floating diffusion region;
a first drive line connected to a gate of the first transfer transistor;
a second drive line connected to a gate of the second transfer transistor; and
a drive circuit that applies a drive signal to each of the first drive line and the second drive line, wherein
the first photoelectric conversion section, the first transfer transistor, and the floating diffusion region configure a first pixel,
the second photoelectric conversion section, the second transfer transistor, and the floating diffusion region configure a second pixel,
the drive circuit applies a first drive signal to the first drive line at a time of read from the first pixel and applies a second drive signal to the first drive line and applies a third drive signal to the second drive line at a time of read from the second pixel, and
a voltage level of at least one of the second drive signal and the third drive signal is lower than a voltage level of the first drive signal.

14. The solid-state imaging device according to claim 13, wherein
a voltage level of the second drive signal is lower than a voltage level of the first drive signal, and
a voltage level of the third drive signal is equal to a voltage level of the first drive signal.

15. The solid-state imaging device according to claim 13, wherein
a voltage level of the second drive signal is lower than a voltage level of the first drive signal, and
a voltage level of the third drive signal is higher than a voltage level of the second drive signal.

16. Electronic equipment comprising:
the solid-state imaging device according to claim 1; and
a processor that executes predetermined processing on image data output from the solid-state imaging device.
